(19) United States
(12) Patent Application Publication
(10) Pub. No.: US 2024/0240302 A1
(43) Pub. Date: Jul. 18, 2024

(54) PRODUCING METHOD OF MASK-SUPPORT ASSEMBLY

(71) Applicant: Olum Material Corporation, Yongin-si (KR)

(72) Inventors: Taek Yong JANG, Seongnam-si (KR); Young Ho LEE, Yongin-si (KR); Jong Il KIM, Seongnam-si (KR)

(73) Assignee: Olum Material Corporation, Yongin-si (KR)

(21) Appl. No.: 18/393,396

(22) Filed: Dec. 21, 2023

(30) Foreign Application Priority Data
Jan. 18, 2023 (KR) 10-2023-0007605

(51) Int. Cl. C23C 14/04; H10K 71/16

(52) U.S. Cl. CPC C23C 14/042; H10K 71/166

(57) ABSTRACT

The present invention relates to a producing method of a mask-support assembly. The producing method of a mask-support assembly for use in a process of forming OLED pixels on a semiconductor wafer may include the steps of: (a) preparing a support; (b) forming a mask metal film on a first surface of the support; and (c) forming a mask including a mask pattern by etching the mask metal film.

### CROSS-REFERENCE TO RELATED APPLICATION(S)

This application claims the benefit under 35 USC § 119(a) of Korean Patent Application No. 10-2023-0007605, filed on Jan. 18, 2023, in the Korean Intellectual Property Office, the entire disclosure of which is herein incorporated by reference for all purposes.

### BACKGROUND

### 1. Field

The following description relates to a producing method of a mask-support assembly. More specifically, the following description relates to a producing method of a mask-support assembly that is used in forming pixels on a semiconductor wafer and enables a mask pattern of ultra-high resolution to be precisely formed.

### 2. Description of Related Art

As a pixel deposition technique in an organic light-emitting diode (OLED) manufacturing process, a fine metal mask (FMM) method for positioning a thin metal mask (or a shadow mask) in contact with or very close to a substrate and depositing an organic material at desired locations is commonly used.

In a conventional OLED manufacturing process, after a mask thin film is prepared, a mask is welded and fixed to an OLED pixel deposition frame and then is used. In the fixing process, there is a problem in that the mask of a large area is not well aligned. Also, in the process of welding and fixing the mask to the frame, there is a problem in that the mask sags or twists with the load since the mask film is too thin and has a large area.

In an ultra-high-resolution OLED manufacturing process, small defects of several μm may lead to pixel deposition failure, and thus there is a need to develop technology that is capable of preventing deformation of a mask, such as sagging or twisting of a mask, and clearly aligning the mask.

Recently, a microdisplay which is applied to a virtual reality (VR) device has drawn attention. A microdisplay is required to provide a much smaller screen size than those of the existing displays and still realize high quality within the small screen in order to display an image directly in front of a user's eye in a VR device. Therefore, smaller mask patterns than those of a mask used in the existing ultra-high-resolution OLED manufacturing process and a finer alignment of the mask before a pixel deposition process are required.

### SUMMARY

Therefore, the present invention is devised to solve the above-mentioned problems of the related art and provides a mask-frame assembly capable of realizing ultra-high definition pixels of a microdisplay, and a producing method thereof.

Moreover, an object of the present invention is to provide a mask-support assembly capable of enhancing stability of pixel deposition by allowing a mask to be clearly aligned, and a producing method thereof.

In addition, another object of the present invention is to provide a mask-support assembly providing a uniform stress level over the entire surface of a mask, and a producing method thereof.

In addition, another object of the present invention is to provide a mask-support assembly enabling a mask and a frame to adhere to a target substrate without sagging due to load during an organic light-emitting diode (OLED) pixel formation process, and a producing method thereof.

However, these objects are merely illustrative, and the scope of the present invention is not limited thereto.

The present invention provides a producing method of a mask-support assembly for use in a process of forming OLED pixels on a semiconductor wafer, the producing method including the steps of: (a) preparing a support; (b) forming a mask metal film on a first surface of the support; and (c) forming a mask including a mask pattern by etching the mask metal film.

The support may be a silicon wafer.

In step (b), the mask metal film made of an Invar or Super Invar material may be formed on the substrate by an electroforming method.

The producing method may further include, between steps (a) and (b), (a2) forming a connection portion including at least one of Ni, Cu, Ti, Au, Ag, Al, Sn, In, Bi, Zn, Sb, Ge, or Cd.

In step (b), the mask metal film may be formed on the connection portion by the electroforming method, or the mask metal film produced by a rolling method may be disposed on the connection portion.

The producing method may further include, between steps (b) and (c), performing heat treatment on the mask metal film and the support.

A connection portion including at least one of Fe, Ni, or Si may be formed between the mask metal film and the support.

The producing method may further include, between steps (b) and (c), performing heat treatment on the mask metal film and the support, and the mask metal film and the support may be connected through the connection portion after heat treatment.

The heat treatment may be performed at a temperature in a range of 100° C. to 800° C.

In step (c), an insulating portion including at least one of photoresist, silicon oxide, or silicon nitride may be formed on an upper part of the mask metal film, and the mask metal film exposed between the insulating portions may be etched.

The mask metal film may be etched using at least one of dry etching, wet etching, or laser etching.

The producing method may further include forming a support including an edge portion and a grid portion by etching the support on a second surface opposite to the first surface of the support.

The support and the mask may have a circular shape, and the grid portion may include a plurality of first grid portions extending in a first direction and having both ends connected to the edge portion; and a plurality of second grid portions extending in a second direction perpendicular to the first direction, intersecting with the first grid portions, and having both ends connected to the edge portion.

The producing method may further include, between steps (c) and (d): (c2) adhering a template onto the mask through a temporary adhering portion; and (c3) reducing a thickness of at least a portion where the grid portion is to be formed to 50 μm to 200 μm on the second surface of the support.

Other features and aspects will be apparent from the following detailed description, the drawings, and the claims.

### BRIEF DESCRIPTION OF THE DRAWINGS

FIG. 1 is a schematic view showing a mask-support assembly according to an embodiment of the present invention.

FIG. 2 is a schematic cross-sectional view showing a mask-support assembly according to an embodiment of the present invention.

FIG. 3 illustrates a schematic plan view and schematic cross-sectional views taken along, respectively, lines E-E′ and F-F′ showing a mask according to an embodiment of the present invention.

FIG. 4 is a schematic plan view showing a support according to an embodiment of the present invention.

FIG. 5 illustrates a schematic plan view and a schematic cross-sectional view taken along line G-G′ showing a mask according to another embodiment of the present invention.

FIGS. 6 to 13 are schematic views showing a producing process of a mask-support assembly according to an embodiment of the present invention.

FIG. 14 is a schematic diagram illustrating an organic light emitting diode (OLED) pixel deposition apparatus to which a mask-support assembly according to an embodiment of the present invention is applied.

FIG. 15 is a schematic view showing a mask-frame assembly according to an embodiment of the present invention.

FIG. 16 is a schematic cross-sectional view taken along line A-A′ of FIG. 15.

FIG. 17 is a schematic cross-sectional view showing a mask-frame assembly according to another embodiment of the present invention.

FIGS. 18 to 25 are schematic views showing a producing process of a mask-support assembly according to another embodiment of the present invention.

FIGS. 26 and 27 are schematic views showing a producing process of a mask-frame assembly according to an embodiment of the present invention.

FIGS. 28 to 30 are schematic views specifically showing a process of connecting a support and an adhering support during the producing process of a mask-frame assembly according to an embodiment of the present invention.

FIGS. 31 to 36 are schematic views showing a process of producing an adhering support according to an embodiment of the present invention.

FIGS. 37 and 38 are schematic views showing a process of producing an adhering support according to another embodiment of the present invention.

FIG. 39 is a schematic diagram illustrating an OLED pixel deposition apparatus to which a mask-frame assembly according to an embodiment of the present invention is applied.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed descriptions of the invention will be made with reference to the accompanying drawings illustrating specific embodiments of the invention by way of example. These embodiments will be described in detail such that the invention can be carried out by one of ordinary skill in the art. It should be understood that various embodiments of the invention are different, but are not necessarily mutually exclusive. For example, a specific shape, structure, and characteristic of an embodiment described herein may be implemented in another embodiment without departing from the scope of the invention. In addition, it should be understood that a position or placement of each component in each disclosed embodiment may be changed without departing from the scope of the invention. Accordingly, there is no intent to limit the invention to the following detailed descriptions. The scope of the invention is defined by the appended claims and encompasses all equivalents that fall within the scope of the appended claims. In the drawings, like reference numerals denote like functions, and the dimensions such as lengths, areas, and thicknesses of elements may be exaggerated for clarity.

Hereinafter, to allow one of ordinary skill in the art to easily carry out the invention, embodiments of the present invention will be described in detail with reference to the accompanying drawings.

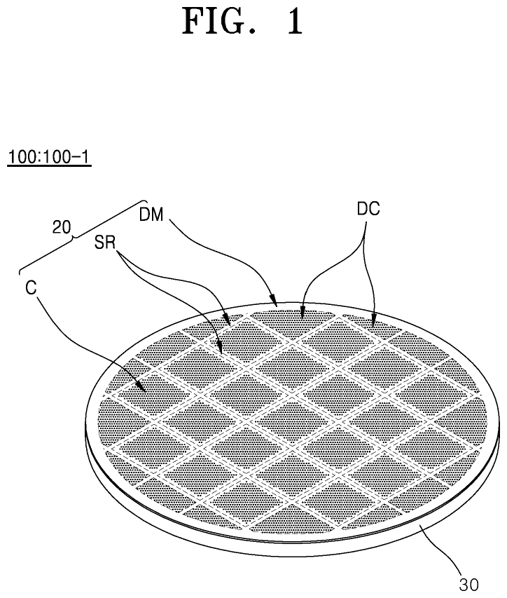

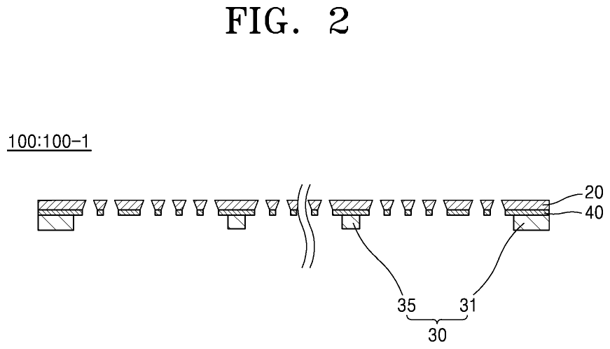

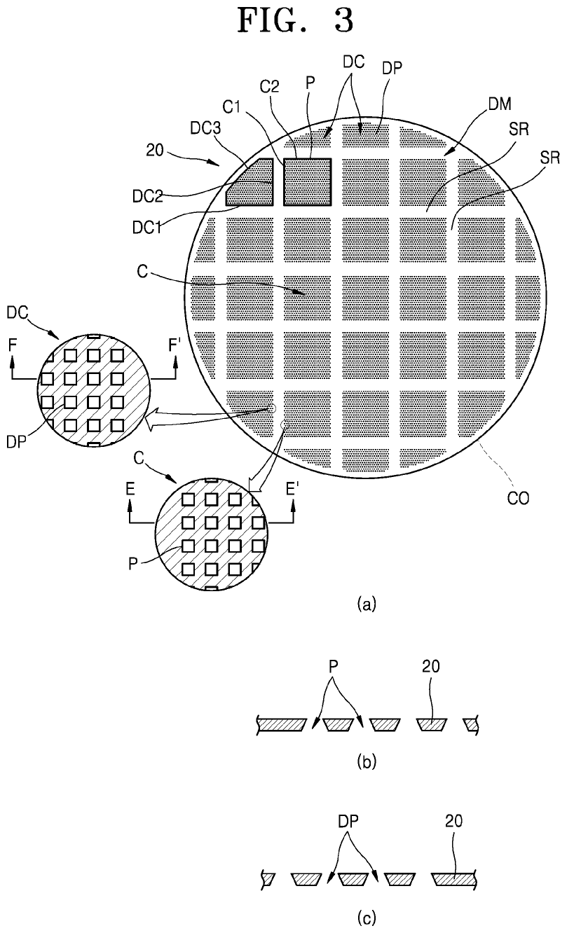

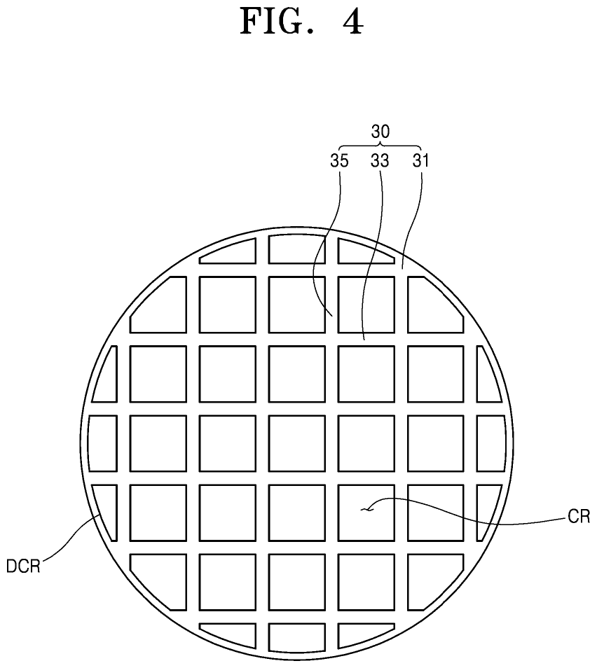

FIG. 1 is a schematic view showing a mask-support assembly 100 (100-1) according to an embodiment of the present invention. FIG. 2 is a schematic cross-sectional view showing a mask-support assembly 100 (100-1) according to an embodiment of the present invention. FIG. 3 illustrates a schematic plan view and schematic cross-sectional views taken along, respectively, lines E-E′ and F-F′ showing a mask 20 according to an embodiment of the present invention. FIG. 4 is a schematic plan view showing a support 30 according to an embodiment of the present invention.

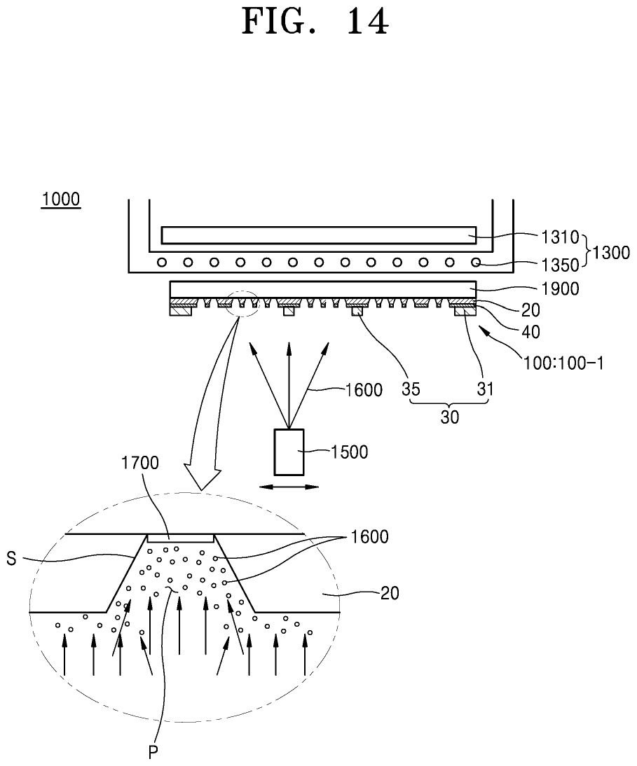

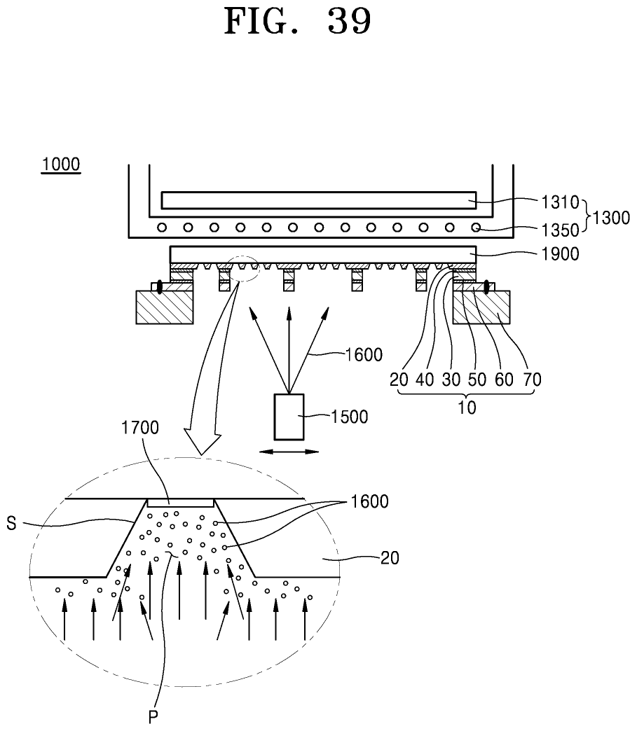

A microdisplay, which is recently applied to a virtual reality (VR) device, may be used in a pixel deposition process for a target substrate 1900 (see FIGS. 14 and 39), such as a silicon wafer or a silicon wafer, rather than for a substrate of a large area. The microdisplay has a screen that is about 1 to 2 inches smaller than the size of the large area substrate because a screen is positioned directly in front of an eye of a user. Moreover, implementation of higher resolution is required since the screen is positioned closely in front of the eye of the user.

Accordingly, the present invention is directed to provide a mask-frame assembly 10 which, rather than being used in a pixel formation process for a target substrate of a large area with a side length exceeding 1,000 mm, allows for a pixel formation process on a semiconductor silicon target wafer 1900 of 200 mm, 300 mm, or 450 mm such that ultra-high-resolution pixels are formed, and a producing method thereof.

For example, currently, quad high definition (QHD) image quality is 500 to 600 pixels per inch (PPI), wherein a size of each pixel is about 30 to 50 μm, and a 4K ultra-high definition (UHD) or 8K UHD image quality has a resolution of up to 860 PPI or up to 1,600 PPI, which is higher than the QHD image quality. A microdisplay directly applied to a VR device or a microdisplay inserted into a VR device is aimed at realizing ultra-high resolution of approximately 2,000 PPI or higher and has a pixel size of about 5 to 10 μm. In the case of a semiconductor wafer or a silicon wafer, a finer and more precise process is possible compared to a glass substrate by utilizing technologies developed in a semiconductor process, and hence the semiconductor wafer or silicon wafer may be employed as a substrate of a high-resolution microdisplay. The present invention is characterized by a mask-frame assembly 100 that allows for formation of pixels on the silicon wafer.

Referring to FIGS. 1 and 2, the present invention is characterized in that a mask 20 has a shape corresponding to a semiconductor wafer (or a silicon wafer) in order to perform a pixel deposition process using the semiconductor wafer as a target substrate 1900 (see FIG. 14). When the shape of the mask 20 corresponds to the semiconductor wafer, it means that the mask 20 has the same shape and size as those of the semiconductor wafer or that the mask 20 has a different size and shape from the semiconductor wafer but is coaxial to the semiconductor wafer while mask patterns P are disposed within the shape of the semiconductor wafer. In addition, the mask 20 that has a shape corresponding to the semiconductor wafer is characterized in that it is integrally connected to the support 30 and is thereby clearly aligned.

The mask-support assembly 100 (100-1) may include the mask 20 and the support 30. The support 30 may serve as a frame that supports the mask 20.

Referring to FIGS. 1 to 3, the mask 20 may include cell portions C, separation portions SR, and a dummy portion DM. Each cell portion C is a portion of the mask 20 that does not come in contact with the support 30 and where the mask patterns P are formed, each separation portion SR is a portion disposed between the cell portions C, and the dummy portion DM is a portion attached to the support 30. Although the cell portion C, the separation portion SR, and the dummy portion DM may be denoted by different names and reference characters according to the formed positions thereof, the cell portion C, the separation portion SR, and the dummy portion DM are not separated regions and are configured to be integrally formed with the same material. In other words, the cell portion C, the separation portion SR, and the dummy portion DM are each part of the mask 20 simultaneously formed in an electroforming process. Hereinafter, the cell portion C, the separation portion SR, and the dummy portion DM may be used interchangeably with the mask 20.

The mask 20 preferably includes an Invar or Super Invar material. Alternatively, the mask 20 may include a metal material that can be electroformed with nickel (Ni), cobalt (Co), titanium (Ti), chromium (Cr), tungsten (W), molybdenum (Mo), or the like and capable of forming silicide with a silicon component of the support 30. Alternatively, the mask 20 may include a Super Invar material containing three or more components, including Co. The mask 20 may have a circular shape to correspond to the circular semiconductor wafer. The mask 20 may have a size equal to or greater than the size of a silicon wafer of 200 mm, 300 mm, 450 mm, or the like.

A conventional mask has a shape of rectangle, polygon, or the like to correspond to a substrate of a large area. In addition, a frame also has a shape of rectangle, polygon, or the like to correspond to the mask. Since the mask has angled corners, there may be a problem in that stress is concentrated on the corners of the mask. Concentration of stress may cause different force to act on only a portion of the mask, which may twist or distort the mask, leading to a failure of pixel alignment. In particular, at an ultra-high resolution of 2,000 PPI or higher, stress concentration on the corners of the mask should be avoided.

Accordingly, the mask 20 of the present invention has a circular shape, and thus has no corners. That is, the dummy portion DM of the mask 20 may have a circular shape and have no corners. Since there is no corner, it is possible to solve the problem that different force acts on a specific portion of the mask 20, and the stress may be uniformly distributed along a circular edge. Accordingly, the mask 20 may contribute to clear pixel alignment without being twisted or distorted, and mask patterns P of 2,000 PPI or higher may be realized. The edge of the mask 20 may be positioned inward of the edge of the support 30, match the edge of the support 30, or be formed to encase the sides of the edge of the support 30. The present invention performs a pixel deposition process by matching a circular semiconductor wafer (or a circular silicon wafer) having a low coefficient of thermal expansion and the circular mask 20 in which the stress is uniformly distributed along the edge, so that pixels with a size of approximately 5 to 10 μm may be deposited.

A plurality of mask patterns P may be formed in the cell portion C. The mask patterns P are a plurality of pixel patterns P that correspond to red (R), green (G), and blue (B) pixels. Sides of each mask pattern P may have a sloped shape, a tapered shape, or a shape in which a pattern width gradually increases from the upper part toward the lower part. A number of mask patterns P may be grouped to form a single display cell portion C. The display cell portion C may have a diagonal length of approximately 1 to 2 inches, and may be a portion that corresponds to one microdisplay. Alternatively, the display cell portion C may be a portion that corresponds to a plurality of displays.

The mask pattern P may have a substantially tapered shape, and the pattern width may be several to dozens of micrometers (μm), preferably approximately 5 to 10 μm (resolution of 2,000 PPI or higher).

The mask 20 may include a plurality of cell portions C. The plurality of cell portions C may be arranged at predetermined intervals in a first direction (x-axis direction) and in a second direction (y-axis direction) that is perpendicular to the first direction. FIG. 1 illustrates that 21 cell portions C are arranged along the first and second directions, but the present invention is not limited thereto. The separation portions SR may be disposed between the cell portions C. The cell portions C and the separation portions SR are positioned closer to the central part of the mask 20 than the dummy portion DM.

Referring to FIGS. 1, 2, and 4, the support 30 may include an edge portion 31, a plurality of first grid portions 33, and a plurality of second portions 35. Although the edge portion 31, and the first and second grid portions 33 and 35 are denoted by different names and reference numerals, the cell portion C, the edge portion 31 and the first and second grid portions 33 and 35 are not separated regions and are configured to be integrally formed with the same material. Hereinafter, the edge portion 31 and the first and second grid portions 33 and 35 may be used interchangeably with the support 30.

The support 30 is preferably made of a silicon material, and more preferably, the support 30 may be formed from a silicon wafer and made of a monocrystalline silicon material. The edge portion 31 of the support 30 may have a circular shape such that the support 30 corresponds to a circular semiconductor wafer that is a target substrate 1900 (see FIG. 14). The support 30 may have a shape of the same size or at least larger than the mask 20 so that the mask 20 can be connected to an upper part of the support 30.

The edge portion 31 may define the outer shape of the support 30, with an edge shaped corresponding to the mask 20. The edge portion 31 may have a circular shape.

The plurality of first grid portions 33 may extend in the first direction and connect at both ends to the edge portion 31. In addition, the plurality of second grid portions 35 may extend in the second direction perpendicular to the first direction, intersecting with the first grid portions 33, and connect at both ends to the edge portion 31. The first grid portions 33 are arranged in parallel to each other with predetermined intervals, and the second grid portions 35 are also arranged in parallel to each other with predetermined intervals. Also, since the first and second auxiliary grid portions 33 and 35 intersect with each other, empty regions CR, in the form of a matrix, may appear at the intersecting portions. These empty regions CR where the cell portions C of the mask 20 are disposed are referred to as “cell regions CR” (see FIG. 4).

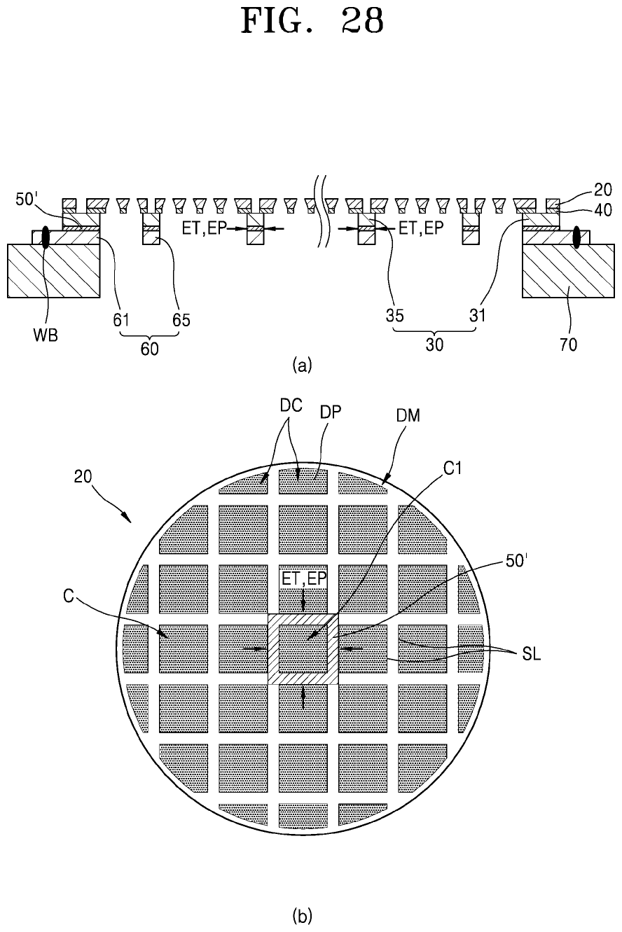

The thickness of the support 30 may be greater than the thickness of the mask 20. In order to realize mask patterns P of 2,000 PPI or higher, the thickness of the mask 20 may be formed in the range of approximately 2 μm to 12 μm. If the mask 20 is thicker than the aforementioned thickness, it may be difficult to form the mask patterns P, having an overall tapered shape, to have the width or spacing that meets the desired resolution. The support 30 may be formed to have a thickness of approximately 50 μm to 200 μm such that it has sufficient rigidity to support the mask 20 and can be tensioned on a cell portion-by-cell portion basis (see FIGS. 28 to 30).

For example, the edge portion 31 and the first grid portion 33/second grid portion 35 in the support 30 may have the same thickness. By applying thickness reduction to a silicon wafer, the edge portion 31 and the first and second grid portions 33, 35 may have a thickness of approximately 50 μm to 200 μm.

In another example, the thickness of the edge portion 31 may be greater than the thickness of the first grid portion 33/the second grid portion 35 in the support 30. The edge portion 31 may serve as a frame in the mask-support assembly 100 (100-1) and may be thicker than the first and second grid portions 33 and 35 in order to prevent the support 30 from deforming or warping as a whole while having sufficient rigidity to support the mask 20. For example, the thickness of the edge portion 31 may be approximately 700 μm to 1,000 μm when a silicon wafer is directly applied, and approximately 500 μm to 1,000 μm when a predetermined thickness reduction is applied. The thickness of the first and second grid portions 33 and 35 is preferably greater than that of the mask 20 but thinner than the edge portion 31. This is because the first and second grid portions 33 and 35 need to support the mask 20 while allowing the cell regions CR (see FIG. 4) therebetween, through which an organic material 1600 passes, and the thickness of the first and second grid portions 33 and 35 should not cause shadow effect when the organic material 1600 passes through. The thickness of the first and second grid portions 33 and 35 may be approximately 50 μm to 200 μm.

On the other hand, in the case where the cell portion C of the mask 20 is in quadrilateral shape, if only the cell portion C is formed on the mask 20, there may be a problem of uneven stress levels in each region of the cell portion C and the dummy portion DM with a circular edge. Furthermore, when only the cell portion C is formed, as there are no separately penetrating openings in the dummy portion DM, the dummy portion DM deforms less under stress, while the cell portion C exhibits significant deformation under the same stress. The mask-frame assembly 10 should maintain a clear position of the cell portion C to construct ultra-high-resolution OLED pixels. Therefore, it is necessary to uniformly align the stress levels acting on the cell portion C and the dummy portion DM. This may be equally applied to the cell region CR and a dummy cell region DCR of the support 30.

Referring back to FIGS. 1 to 3, a plurality of dummy cell portions DC may be formed in the mask 20 of the present invention. The plurality of dummy cell portions DC may be arranged at predetermined intervals in a first direction (x-axis direction) of the cell portion C and in a second direction (y-axis direction) that is perpendicular to the first direction. The predetermined interval between the dummy cell portion DC and the cell portion C may correspond to the predetermined interval between the cell portions C. A separation portion SR may also be disposed between the dummy cell portion DC and the cell portion C.

A length of at least one side DC1 or DC2 of the dummy cell portion DC may correspond to a length of one side C1 or C2 of the cell portion C. The cell portion C may be provided in a quadrilateral shape, and edge sides C1 and C2 of the cell portion C may be formed as straight lines perpendicular to each other. The dummy cell portion DC may be arranged on an extended line of the cell portion C along the first and second directions, but it may be difficult to provide the dummy cell portion DC in a quadrilateral shape due to the nature of being arranged at the edge of the mask 20. The dummy cell portion DC may have a shape with at least some side DC3 having curvature. From another perspective, two to four edge sides of the dummy cell portion DC may be provided as straight lines, and some sides may be provided as curves. In FIG. 3, for example, the dummy cell portion located in the top-left corner is provided with two sides DC1 and DC2 as straight lines of the same length as the edge sides of the cell portion C, and the remaining side DC3 is provided with two shorter straight lines and one shorter curve compared to the edge side of the cell portion C. In another example, the rightmost/leftmost dummy cell portions DC and the uppermost/lowermost dummy cell portions DC may have a substantially angular “C” shape with three sides provided as straight lines, and one side thereof is provided as a curved line.

In addition, a plurality of dummy patterns DP may be formed in the dummy cell portion DC. As shown in FIGS. 2 and 3, the dummy patterns DP may be formed to have the same shape as the mask patterns P. For example, sides of each dummy pattern P may have a sloped shape, a tapered shape, or a shape in which a pattern width gradually increases from the upper part toward the lower part. The plurality of dummy patterns DP may be grouped to form a single dummy cell portion DC. The dummy pattern DP may have a substantially tapered shape, and the pattern width may be several to dozens of micrometers (μm), preferably approximately 5 to 10 μm (resolution of 2,000 PPI or higher).

Meanwhile, the dummy patterns DP may be formed to a specific depth in a predetermined range for the purpose of maintaining uniform stress throughout the entire area of the mask 20, even if they do not penetrate the mask 20 in the thickness direction. Also, the dummy patterns DP may not necessarily have the same shape and size as the mask patterns P, but may be greater than the mask patterns P and may have a shape other than a tapered shape as long as they maintain uniformity of stress throughout the entire area of the mask 20. However, as the shapes of dummy patterns P and the mask patterns P are more identical to each other, the uniformity of stress levels may increase.

Referring to FIG. 4, a plurality of dummy cell regions DCR may be formed in the support 30. The plurality of dummy cell regions DCR may be arranged at predetermined intervals in a first direction (x-axis direction) of the cell region CR and in a second direction (y-axis direction) that is perpendicular to the first direction. The predetermined interval between the dummy cell region DCR and the cell region CR may correspond to the predetermined interval between the cell regions CR. The first and second grid portions 33 and 35 may also be disposed between the dummy cell regions DCR and the cell regions CR. Since the dummy cell regions DCR serve the same function as the dummy cell portions DC described above, the description thereof will be replaced with the above description of the dummy cell portions DC.

Meanwhile, a connection portion 40 may be interposed between the mask 20 and the support 30. The mask 20 may be connected onto the support 30 with the connection portion 40 interposed between them. The edge portion 31 of the support 30 may be connected to the dummy portion DM of the mask 20, and the first and second grid portions 33 and 35 of the support 30 may be connected to the separation portions SR of the mask 20. That is, the separation portions SR may be supported on the first and second grid portions 33 and 35.

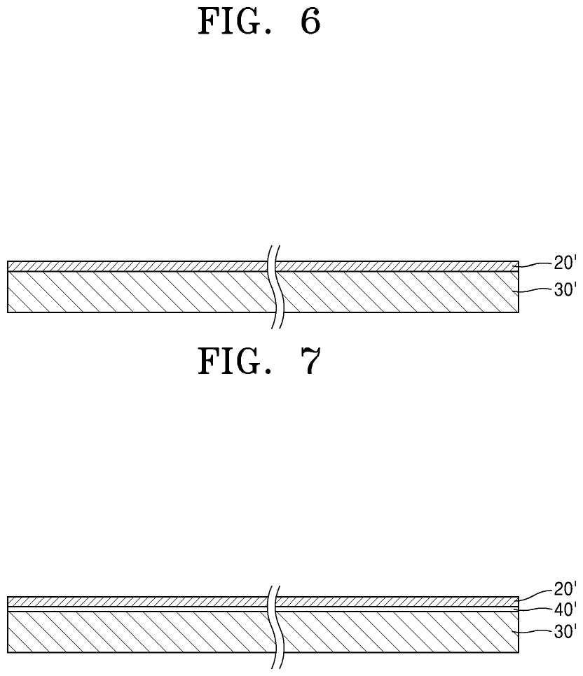

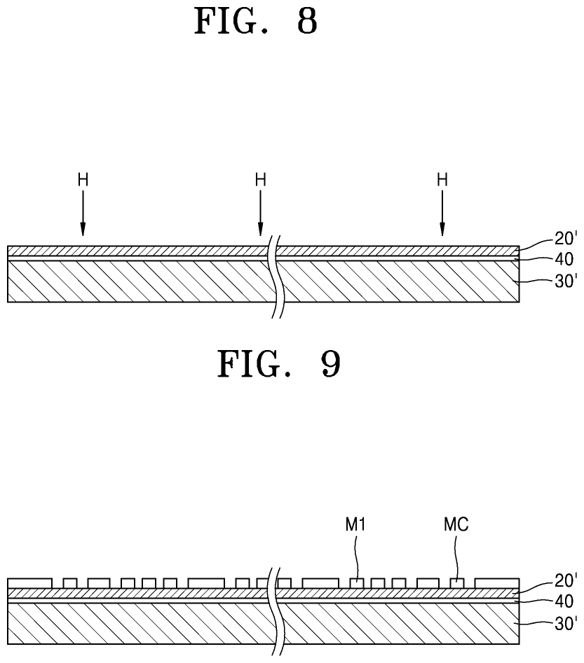

The connection portion 40 may be formed by thermal treatment H (see FIGS. 6 and 8) in a state of a laminate in which the mask 20 is formed on the support 30. According to an embodiment, the connection portion 40 may be provided as an intermetallic compound resulting from the combination of the components of the mask 20 and the support 30. As the Fe and Ni components of the mask 20 and the Si component of the support 30 are combined, the connection portion 40 may be provided as a silicide containing Ni and Si, containing Fe, Ni, and Si, or containing Fe and Ni. The bonding strength of the intermetallic compound allows the mask 20 and the support 30 to be connected to each other through the connection portion 40.

In addition, according to an embodiment, the connection portion 40 may serve as an adhesion layer mediating adhesion, allowing the mask 20 to be formed with higher adhesive strength on the support 30 (see FIGS. 7 and 8). For example, in the case where the support 30 is a silicon wafer, the adhesive strength of the mask 20 is higher when the mask 20, which is made of Invar or Super Invar, is adhered to the support 30 through the connection portion 40 made of Ni, Cu, or the like, than when the mask 20 is directly adhered to the support 30. Taking this into account, the connection portion 40 may contain at least one of Ni, Cu, Ti, Au, Ag, Al, Sn, In, Bi, Zn, Sb, Ge, or Cd.

Referring back to FIG. 3, a crystal orientation (CO) of the (100) or (111) plane of the silicon wafer may not be parallel to the longitudinal directions of the grid portions 33 and 35. The grid portions 33 and 35 may extend along the x-axis direction or the y-axis direction, and the crystal orientation CO of the (100) or (111) plane of the silicon wafer of the support 30 may not be parallel to the x-/y-axis direction (at an angle of 0° or 180°) and may have a predetermined angle other than 0° or 180° with respect to the x-/y-axis direction. In another aspect, the crystal orientation CO of the (100) or (111) plane of the silicon wafer may have a predetermined angle, which is not 0° or 180°, with respect to the x-/y-axis direction in which the plurality of cell portions C are disposed. The silicon wafer is more prone to be broken in the crystal orientation CO of the (100) or (111) plane than in other crystal orientations. As the cell portions C, the separation portions SR, and the like of the mask 20 that correspond to the grid portions 33 and 35 are arranged in a staggered manner in the crystal orientation CO, the risk of breakage of the mask-support assembly 100 is reduced and overall rigidity is increased.

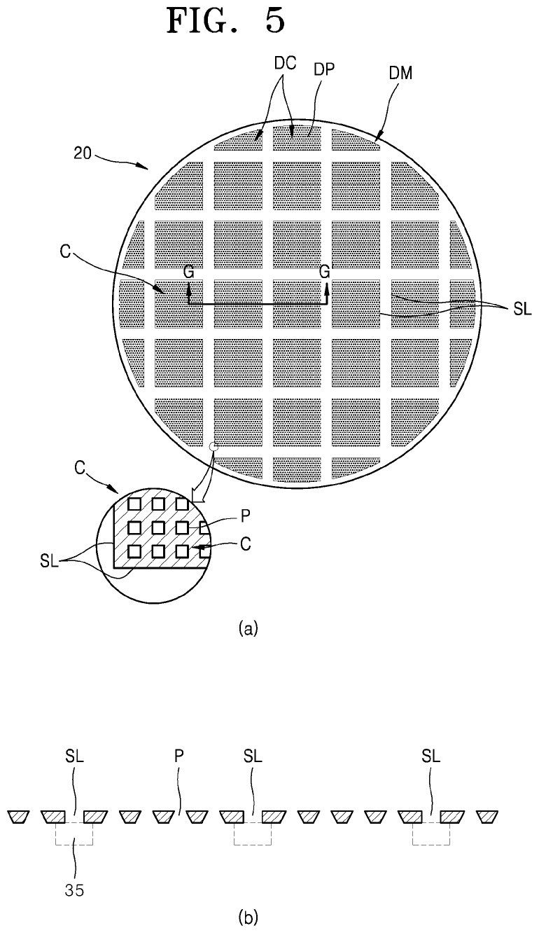

FIG. 5 illustrates a schematic plan view (a) and a schematic cross-sectional view (b) taken along line G-G′ showing a mask according to another embodiment of the present invention.

Referring to FIG. 5, a mask 20 according to another embodiment may include a plurality of cell portions C including a plurality of mask patterns P. In addition, slit lines SL may be formed between each cell portion C. The cell portions C may be spaced apart from each other by the slit lines SL. Additionally, each pair of neighboring cell portions C may be supported at one side on the same grid portion 35. Referring to (b) of FIG. 5, it can be seen that the right and left sides of two neighboring cell portions C are supported on a second grid portion 35 represented by a dotted line.

Unlike the mask 20 in which the cell portions C are connected to each other through the separation portions SR as shown in FIG. 2, the cell portions C of the mask 20 shown in FIG. 5 may be spaced apart from each other by the slit lines SL. The surface of the underlying support 30 (the edge portion 31 and the first and second grid portions 33 and 35) may be exposed between the cell portions C by the slit lines SL. As will be described below, as the cell portions C exist independently of each other by the slit lines SL without being connected to each other, each cell portion C may be sequentially connected onto the adhering support 200 as described below with reference to FIGS. 28 to 30. Additionally, the slit lines SL ensure that residual stress is contained within each individual cell portion C without affecting other cell portions C.

FIGS. 6 to 13 are schematic views showing a producing process of a mask-support assembly 100 (100-1) according to an embodiment of the present invention.

Referring to FIG. 6, a support 30′, which is a conductive substrate 30′, is prepared. The support 30′ may be made of a conductive material to enable electroforming. To achieve both conductivity and low resistance, the support 30′ may be highly doped at a concentration higher than or equal to 10¹⁹ cm⁻³. The doping may be performed over the entire support 30′ or limited to the surface of the support 30′. According to an embodiment, the surface resistance of the support 30′ may be 5×10⁻⁴ to 1×10⁻² ohm cm. The support 30′ may be used as a cathode electrode during electroforming.

Unlike metals with a metal oxide on the surface or polycrystalline silicon with grain boundaries, doped monocrystalline silicon, being free of defects, allows for the uniform formation of an electric field across the entire surface during an electroforming process, which results in a uniform plated film (or mask 20). The mask 20 prepared with the uniform plated film may further improve the image quality of OLED pixels. Moreover, since a process for removing or preventing defects is not additionally required, process costs may be reduced and productivity may be increased.

Then, for example, electroforming may be directly performed on the support 30′ to form a mask metal film 20′. The support 30′ is used as a cathode body and an anode body (not shown) facing the support 30′ is prepared. The anode body may be immersed in a plating solution (not shown), and the support 30′ may be entirely or partially immersed in the plating solution. The mask metal film 20′ may be understood to be in a state without mask patterns P before the formation of a mask 20. The mask metal film 20′ may be formed over the entire upper surface of the support 30′ or in some regions.

Meanwhile, the composition of the mask metal film 20′ may be controlled so that the mask 20 has a coefficient of thermal expansion (CTE) similar to that of a silicon material of the support 30′. The mask metal film 20′ should have a CTE similar to that of the support 30 to prevent sagging of the mask 20 on the support 30, which serves as a frame. In addition, this may minimize changes in pixel position accuracy (PPA), which is the alignment error of cell portions C and mask patterns P on the support 30.

Taking this into account, the composition of the mask metal film 20′ may be controlled such that the CTE of the support 30 made of silicon and the CTE of the mask 20 after heat treatment H, which will be described below, become approximately (3.5±1)×10⁻⁶/° C. Even when the mask metal film 20′ is made of Invar, the CTE of the mask metal film 20′ may be controlled to be as close or similar as possible to the CTE of the support 30 made of silicon, by electroforming with varying composition ratios of Fe and Ni. Alternatively, the CTE of the mask metal film 20′ may be controlled to be smaller or greater than that of the support 30 so that the mask metal film 20′ can be tightly connected onto the support 30 depending on process temperature conditions.

Additionally, the mask metal film 20′ may be configured as a laminate with two or more plated layers such that the mask metal film 20′ has a CTE similar to that of a silicon material of the support 30′. In this case, a first mask layer may be formed of a metal material capable of forming silicide with the support 30′. The first mask layer may be formed of a material, such as Ni, Co, Ti, Cr, W, Mo, or the like, which exhibits high adhesion to the support 30, when produced by electroforming. A second mask layer may be made of a material, such as Invar, Super Invar, or the like, which exhibits a low CTE, when produced by electroforming. As the first and second mask layers have different CTEs, the CTE of the mask metal film 20′ may be controlled by adjusting the thickness ratio of the first and second mask layers. The thickness ratio of the first and second mask layers may be controlled by adjusting the electroforming duration.

Meanwhile, as shown in FIG. 19 which will be described below, the mask metal film 20′ may further include a plated film 22 formed on side surfaces of the support 30′.

Also, in the case of performing heat treatment H which will be described below, the mask metal film 20′ formed by electroforming needs to be well adhered to the support 30′ without peeling off. To this end, other approaches may be considered in addition to electroforming on the upper and side surfaces of the support 30′.

In one approach, a native oxide of the support 30′ on which electroforming is performed may be controlled. An oxide may be formed on the surface of the support 30′ made of a silicon wafer material. On the surface with such an oxide, a uniform electric field may not be generated, and hence the plated film (the mask metal film 20′) may not be uniformly produced, and the adhesion between the produced plated film (the mask metal film 20′) and the support 30′ may be low. Therefore, a process of removing native oxide is preferably followed by an electroforming process.

In another approach, another film may be further formed to mediate adhesion between the plated film (the mask metal film 20′) and the support 30′. In addition to a barrier film, which will be described below, a film or a combination of films providing adhesion to both surfaces of the film may be used.

In still another approach, the surface of the support 30′ may be pre-treated before electroforming. Through physical treatment or chemical treatment, the plated film (the mask metal film 20′) produced in the electroforming process may be formed on the support 30′ with stronger adhesion. In addition, by controlling the plating method in the electroforming process, the plated film (the mask metal film 20′) may be formed on the support 30′ with stronger adhesion.

In another example, a mask metal film 20′ produced by a rolling method may be disposed on the support 30′. The mask metal film 20′ is preferably disposed on the support 30′ in a flat-spread state. When the mask metal film 20′ produced by a rolling method is disposed, the support 30′ does not necessarily have conductivity.

On the other hand, according to another embodiment, the mask metal film 20′ may be formed after forming a connection portion 40′, as shown in FIG. 7. The connection portion 40′ may be formed on the support 30′ by electroforming. Alternatively, when the material of the connection portion 40′ is not suitable for electroforming, the connection portion 40′ may be formed using sputtering or brazing. When produced by electroforming, the connection portion 40′ may be formed of a material such as Ni, Cu, Ti, Au, Ag, Al, etc. that exhibits high adhesion to the support 30′. Alternatively, when produced by sputtering or brazing, the connection portion 40′ may be formed of a material such as Sn, In, Bi, Zn, Sb, Ge, Cd. etc. that exhibits high adhesion to the support 30′.

Since the connection portion 40′ may serve to increase the adhesion between the support 30′ (or conductive substrate 30′) and the mask metal film 20′ and to enable electroforming of the mask metal film 20′ on the connection portion 40′, the connection portion 40 preferably has a thinner thickness than that of the mask metal film 20′. Taking this into account, it is preferable that the thickness of the connection portion 40′ does not exceed 20% of the thickness of the mask metal film 20′ (or mask 20). In particular, if the thickness of the connection portion 40′ is too thin, it may be difficult to achieve the desired adhesion between the support 30′ and the mask metal film 20′. On the other hand, if the thickness of the connection portion 40′ is too thick, it may impact the electroforming quality of the mask metal film 20′, or after etching EC of the support 30′, which will be described below, excessive residue of the connection portion 40 may occur, causing issues with obscuring the mask pattern P. Therefore, it is preferable for the thickness of the connection portion 40′ to be in the range of 0.1 μm to 1 μm.

As shown in FIG. 7, the mask metal film 20′ may be electroformed after forming of the connection portion 40′, or the mask metal film 20′ produced by a rolling method may be disposed on the connection portion 40′.

Then, referring to FIG. 8, the mask metal film 20′ and the support 30′ may be subjected to heat treatment H.

Generally, compared to an Invar thin plate produced by rolling, an Invar thin plate produced by electroforming has a higher CTE. Therefore, performing heat treatment on the Invar thin plate may reduce the CTE. However, there may be slight deformation in the Invar thin plate during this heat treatment process. If heat treatment is performed only on the mask metal film 20′ that exists separately, the entire mask metal film 20′ may be warped, or slight deformation may occur in the mask pattern P. Therefore, when heat treatment is performed in a state where the support 30′ and the mask metal film 20′ are fixed and adhered to each other, such deformation may be prevented.

In addition, the Invar thin plate produced by electroforming and a silicon wafer have almost the same CTE, approximately 3 to 4 ppi Thus, even when the heat treatment H is performed, the mask metal film 20′ and the support 30′ have the same or similar degree of thermal expansion, preventing misalignment due to thermal expansion and avoiding subtle deformation in the mask pattern P.

Moreover, the present invention is characterized by the connection of the mask metal film 20′ and the support 30′ through the heat treatment H. For example, when the mask metal film 20′ is directly formed on the support 30′ as shown in FIG. 6, the heat treatment may be performed at a temperature in the range of approximately 300° C. to 800° C. During the heat treatment H process, a connection portion 40 may be formed between the mask metal film 20′ and the support 30′. According to an embodiment, the connection portion 40 may be provided as an intermetallic compound resulting from the combination of the components of the mask metal film 20′ and the support 30′. As the Fe and Ni components of the mask metal film 20′ and the Si component of the support 30′ are combined, the connection portion 40 may be provided as a silicide containing Ni and Si, containing Fe, Ni, and Si, or containing Fe, Ni, and other components. The bonding strength of the intermetallic compound may allow the mask metal film 20′ and the support 30′ to be attached to each other through the connection portion 40.

According to an embodiment, formation conditions of the connection portion 40 provided as a silicide require the following electroforming pre-treatment/electroforming conditions. First, the mask metal film 20′ may be electroformed on the support 30′ that has been highly doped at a concentration higher than or equal to 10¹⁹ cm⁻³ and has a surface resistance of approximately 5×10⁻⁴ to 1×10⁻² ohm cm. Second, before electroforming of the mask metal film 20′, the surface of the support 30′ made of a silicon wafer material may be subjected to HF treatment to form a Si surface with controlled SiO. Third, by initially forming Ni-rich Fe—Ni and adjusting the composition to a Ni content of 35 to 45%, Ni-silicide may be promoted. Alternatively, before the electroforming of the mask metal film 20′ with Fe—Ni composition, a first mask layer of Ni, Co, Ti, etc., may be added as a glue layer to promote the formation of silicide.

Additionally, according to an embodiment, the heat treatment H may be performed at temperatures ranging from 300° C. to 800° C., and the heat treatment H process may be carried out in multiple steps. As a 2-step heat treatment, Ni2Si may be formed in the low-temperature range (approximately 250° C. to 350° C.), adhering the mask metal film 20 to the support 30′, followed by gradually raising the temperature to the high-temperature range (approximately 450 to 650° C.) to perform the heat treatment. In the case of an Invar mask produced by electroforming, due to its microcrystalline and/or amorphous structure, a rapid increase in temperature during heat treatment may lead to the detachment or separation of the Invar mask from the silicon wafer support due to volume contraction. Therefore, it is preferable to perform heat treatment by gradually raising the temperature to high temperature after adhering the Invar mask to the silicon wafer support at low temperature.

In addition, according to an embodiment, a reducing atmosphere should be maintained during the heat treatment H. The reducing atmosphere may be formed as H₂, Ar, or N₂ atmosphere, and may preferably use a dry N₂ gas to prevent oxidation of the Invar mask. In order to prevent oxidation of the Invar mask, it is necessary to manage the O₂ concentration to be less than 100 ppm. Alternatively, a vacuum atmosphere of <10⁻² torr may be formed. The duration may range from 30 minutes to 2 hours.

With the formation of the connection portion 40 (adhesive layer) such as Ni silicide, (Ni, Fe)Si silicide, etc., on the Ni, Fe—Ni interface of the electroformed mask metal film 20′ on the silicon wafer support 30′, the mask metal film 20′ and the support 30′ may be connected to each other with the adhesive layer 40 interposed therebetween.

Meanwhile, to control the reaction of Ni and Fe—Ni with Si during the heat treatment H, a barrier film (not shown) may be formed on the support 30′ before electroforming the mask metal film 20′ on the support 30′. The barrier film may prevent the components (e.g., Ni and Fe—Ni) of the mask metal film 20′ from permeating uncontrollably into the silicon support 30′. Also, the barrier film preferably has conductivity to allow electroforming to take place on the surface. Taking this into account, the barrier film may include a material, such as titanium nitride (TiN), titanium/titanium nitride (Ti/TiN), tungsten carbide (WC), titanium tungsten (WTi), graphene, or the like. A thin film formation process such as deposition of barrier film may be used without limitations. The barrier film may control the reaction of Fe and Ni with Si to ensure the formation of a uniform silicide and allow the mask metal film 20′ and the connection portion 40 to be attached to each other with appropriate adherence strength. In addition, the barrier film may be configured as a film or a combination of films capable of providing predetermined adhesion or adherence so that the mask metal film 20′ is not separated from the support 30′ in a state in which the mask metal film 20′ is electroformed on the support 30′.

The thickness of the connection portion 40 (silicide thickness) may be controlled to 10 to 300 nm by adjusting temperature and time, facilitating the connection between the support 30′ and the mask 20.

In another example, when the connection portion 40′ is formed between the mask metal film 20′ and the support 30′, as shown in FIG. 7, heat treatment H may be performed at temperatures ranging from 100° C. to 800° C., preferably in the low-temperature range of approximately 100° C. to 400° C. During the heat treatment (H) process, a predetermined pressure may be applied to perform the heat treatment with less heat. During the heat treatment (H) process, a phase change occurs where the connection portion 40 between the mask metal film 20′ and the support 30′ is melted by the heat treatment and then solidifies again. Through this phase change, the connection portion 40 may mediate the connection between the mask metal film 20′ and the support 30′. The connection portion 40 may act as an adhesion layer or a glue layer. In another aspect, the connection may be achieved by altering the interfacial state between the mask metal film 20′, the support 30′, and the connection portion 40 in a manner that metal components of the connection portion 40 diffuse into the mask metal film 20′ and the support 30′, or conversely, the components of the mask metal film 20′ and the support 30′ diffuse into the connection portion 40, or in a manner that the components of the mask metal film 20′, the support 30′, and the connection portion 40 diffuse mutually into each other.

Alternatively, the heat treatment process may be omitted, considering the connection strength between the mask metal film 20′ and the support 30′.

Next, referring to FIG. 9, patterned insulating portions M1 and MC may be formed on one surface of the mask metal film 20′. The insulating portions M1 and MC may be made of a photoresist material or a hard insulating material such as silicon oxide or silicon nitride.

The insulating portion M1 may be formed on the mask metal film 20′ by a method such as deposition of silicon oxide or silicon nitride. Alternatively, a photoresist may be formed using a method such as printing or the like.

In addition to the insulating portion M1, the patterned insulating portion MC (or a dummy insulating portion MC) may be further formed on one surface of the mask metal film 20′. The insulating portion M1 may be formed on a region corresponding to the cell portion C and the insulating portion MC may be formed on a region corresponding to the dummy cell portion DC. The shape of the insulating portion MC may be the same as that of the insulating portion M1. The insulating portion MC and the insulating portion M1 may be formed together in the same process.

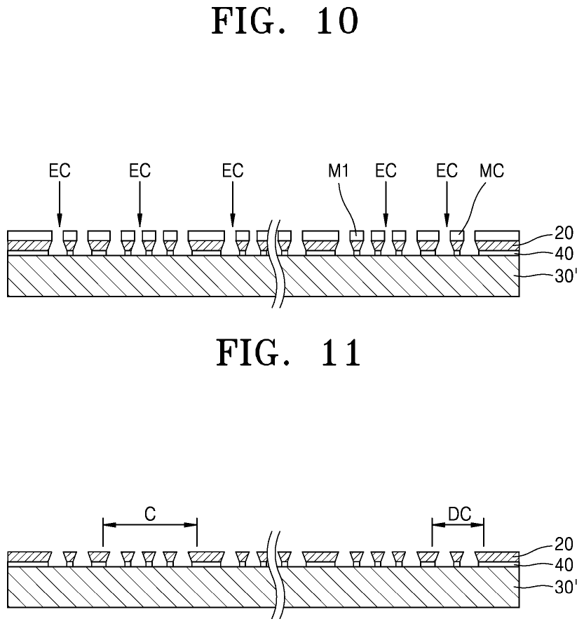

Then, referring to FIG. 10, the mask metal film 20′ may be subjected to etching EC. Etching EC may be performed on the surface of the mask metal film 20′ exposed between patterns of the insulating portions M1 and MC. Dry etching or wet etching may be used for etching EC, but dry etching, which has anisotropic characteristics and allows precise etching to a desired width, is preferable. Alternatively, laser etching using femtosecond laser, picosecond laser, or the like may be used for precise etching. In the case of laser etching, the process of forming the insulating portions M1 and MC may be omitted. Additionally, the etching EC method may be applied without limitation so that a mask pattern P has a shape that increases in width from top to bottom. Thus, the mask pattern P having a (reverse) tapered shape for preventing shadow effect may be provided.

Thereafter, referring to FIG. 11, the insulating portions M1 and MC may be removed. By etching EC of the mask metal film 20′, mask patterns P, dummy patterns DP, etc., may be formed in the cell region C and the dummy cell region DC, and the mask metal film 20′ may be produced into the mask 20.

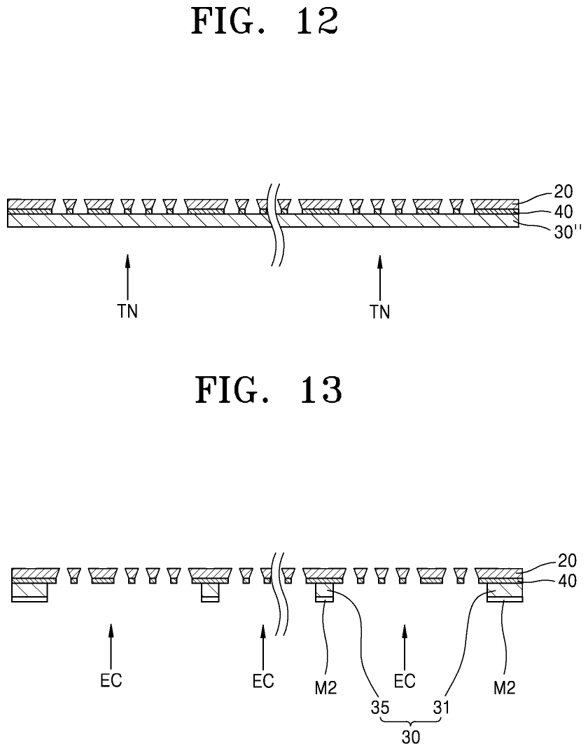

Subsequently, referring to FIG. 12, a thickness reduction process TN of the support 30′ (or conductive substrate 30′) may be performed. The thickness reduction process TN may be performed on a lower surface (second surface), which is opposite to the upper surface (first surface) of the support 30′ in contact with the mask 20. The thickness reduction process TN may be performed using lapping, polishing, buffing, etc.

The thickness reduction process TN may be performed on the entire lower surface (second surface) of the support 30′. Alternatively, the thickness reduction process TN may be performed on a central part of the support 30′. The thickness reduction process TN may be performed on a region of the support 30′ that corresponds to a region where cell portions C of the mask 20 are disposed. Alternatively, the thickness reduction process TN may be performed on a region where the first and second grid portions 33 and 35 are to be formed, and may not be performed on a region where the edge portion 31 is to be formed. The region where the first and second grid portions 33 and 35 are to be formed may even include regions that correspond to at least a part of the cell portions C, the separation portions SR, and the dummy portion DM of the mask 20.

Accordingly, in the support portion 30′ subjected to the thickness reduction process TN, a thickness T2 of the grid portions 33 and 35 is thinner than a thickness T1 of the edge portion 31, and at least a step may be formed between the grid portions 33 and 35 and the edge portion 31.

On the other hand, the thickness reduction process TN may be divided into stages, wherein a primary thickness reduction process may be performed over the entire lower surface (second surface) of the support 30′ and then a secondary thickness reduction process may be performed on the region where the first and second grid portions 33 and 35 are to be formed.

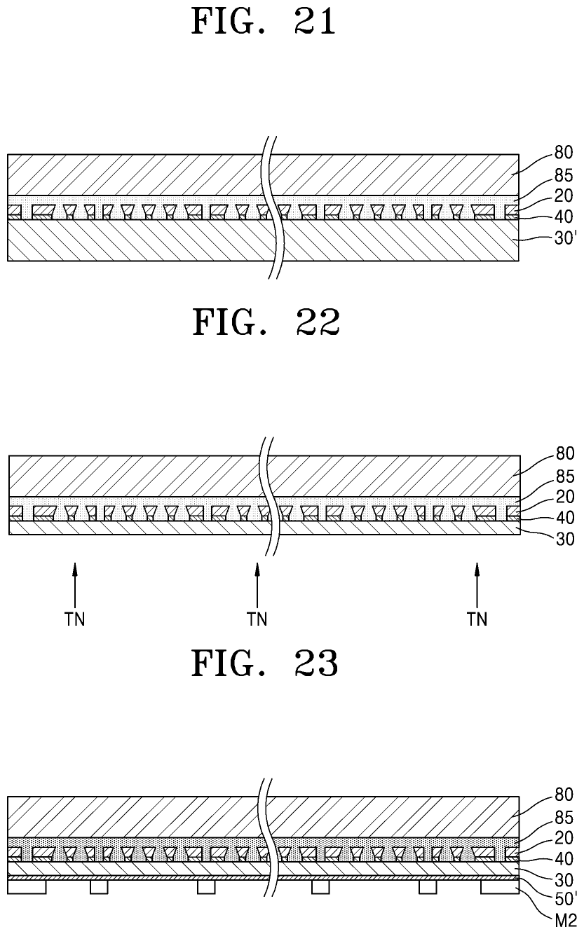

Optionally, the thickness reduction process TN may be performed after a template 80 is adhered to the upper surface of the mask 20, which will be described below in FIGS. 21 and 22. Optionally, as far as shadow effect does not occur, the thickness reduction process TN may not be performed for the region where the first and second grid portions 33 and 35 are to be formed. In this case, the process described in FIG. 11 may directly proceed to the process described below in FIG. 13.

Then, referring to FIG. 13, the support 30′ may be subjected to etching EC. Etching EC may be performed on the second surface (lower surface) opposite to the first surface (upper surface) of the support 30′ to which the mask 20 is adhered. Exposed portions of the lower surfaces of the support 30′ and an adhesive portion 50′ not covered by an insulating portion M2 may be subjected to etching EC. Etching EC may be performed on a region of the support 30′ corresponding to the cell portions C of the mask 20. A region that corresponds to the separation portion SR of the mask 20 is not subjected to etching. Additionally, etching EC may be performed on regions of the support 30′ corresponding to the dummy cell portions DC of the mask 20. Etching EC may also be performed on the adhesive portion 50′, and etching EC of the adhesive portion 50′ and the support 30′ may be performed in a single process or separate processes.

The support 30 after etching EC may take a form including the edge portion 31 and the grid portions 33 and 35. The edge portion 31 and the grid portions 33 and 35 may have the adhesive portion 50′ formed on their lower surfaces. The remaining form of the adhesive portion 50′ may correspond to the shape of the edge portion 31 and grid portions 33 and 35.

The template 80 may adhere to and support the mask 20/the support 30 and prevent the support 30 from deforming during the etching process EC, or when an empty region, such as the cell regions CR/the dummy cell regions DCR (see FIG. 4), increases in the support 30 while only the edge portion 35 and the grid portions 30 and 35 remain after the etching EC process. Also, the template 80 may protect the surface of the mask 20 during the etching EC process.

To ensure clear visibility of the edge portion 31 and the grid portions 33 and 35, it is preferable to use a dry etching method with anisotropic etching characteristics. Since the support 30′ (or conductive substrate 30′) is a silicon wafer, there is an advantage in that etching EC can be performed by utilizing existing semiconductor-related technologies and Micro-Electro Mechanical System (MEMS)-related technologies.

Moreover, the etching EC process in FIG. 13 may employ wet etching, instead of dry etching. Wet etching, having isotropic etching characteristics, may induce undercutting of the insulating layer M2 on the second surface (lower surface) of the support 30′. Also, due to the isotropic etching characteristics, side surfaces of the edge portion 31 and the first and second grid portions 33 and 35 may be formed to be tapered. In this case, since organic material sources 1600 can move at an inclined angle along the tapered side surface, shadow effect may be primarily prevented in the support 30 and then secondarily prevented in the tapered mask patterns P.

According to an embodiment, a laminate of the mask 20/the support 30′/the adhesive portion 50′ may be immersed in an etchant for Si wet etching to perform the etching EC. Si etchant may be a solution of ultrapure water with 1 to 25% KOH or NaOH. Alternatively, a solution of ultrapure water with 1 to 25% of TMAH may be used. The etching process may be conducted at temperatures ranging from room temperature to 80° C.

The regions opened by a hard mask such as PR or SiN, SiO, etc., allow silicon (Si) etching to occur, forming the endpoint of etching at the interface between the mask 20 and the support 30′. In other words, only the silicon wafer undergoes etching EC, and the mask 20 may remain unetched.

Furthermore, when Si etching is performed by selecting the orientation of the silicon wafer, anisotropic etching is possible, allowing for the adjustment of the taper inclination angles of the side surfaces of the edge portion 31 and first and second grid portions 33 and 35 described above.

In addition, according to an embodiment, when using an etchant solution with an OH base for Si wet etching, it may be difficult to use conventional PR materials for the insulating portion M2. Therefore, when using an OH-based etchant solution, the insulating portion M2 may be formed using epoxy-based PR or a nitride or oxide-based (such as SiN, SiO, or the like) hard mask.

Furthermore, etching rate of wet etching may significantly vary depending on the crystal orientation of the silicon support 30′. For example, the (100) and (110) planes have a high etching rate for wet etching, whereas the (111) plane has a low etching rate. Accordingly, in the present invention, wet etching and dry etching may be alternately performed for etching EC of the exposed portions on the lower surface of the support 30′.

Wet etching is characterized by low cost and high productivity, but it exhibits a low etching rate on a specific plane. Dry etching, on the other hand, offers the advantage of uniform etching rates on all planes but comes with higher cost and lower productivity. If etching is solely carried out through dry etching, there is a risk of exceeding the operational limits of etching equipment. Thus, wet etching may be initially performed when the (100) and (110) planes are exposed on the lower surface of the support 30′. When the (111) plane is exposed during the wet etching, the (111) plane may be selectively removed through dry etching, followed by another wet etching.

Then, the insulating portion M2 is removed and subsequent processes such as cleaning may be performed to complete the producing of the mask-support assembly 100 (100-1) as shown in FIGS. 1 and 2.

FIG. 14 is a schematic diagram illustrating an organic light emitting diode (OLED) pixel deposition apparatus 1000 to which a mask-support assembly 100 (100-1?) according to an embodiment of the present invention is applied.

Referring to FIG. 14, an OLED pixel deposition apparatus 1000 includes a magnet plate 1300 in which a magnet 1310 is accommodated and a cooling water line 1350 is disposed, and a deposition source supply 1500 configured to supply organic material sources 1600 from a lower part of the magnet plate 1300.

A target substrate 1900, such as glass, on which the organic material sources 1600 are to be deposited may be interposed between the magnet plate 1300 and the deposition source supply 1500. The mask-support assembly 100 (100-1) for enabling deposition of the organic material sources 1600 per pixel may be positioned in contact with or very close to the target substrate 1900. The magnet 1310 may generate a magnetic field and the mask-support assembly 100 (100-1) may adhere to the target substrate 1900 due to the attraction by the magnetic field.

The deposition source supply 1500 may supply the organic material sources 1600 while horizontally reciprocating, and the organic material sources 1600 supplied from the deposition source supply 1500 may pass through the mask patterns P formed on the mask-support assembly 100 (100-1) and be deposited on a surface of the target substrate 1900. The deposited organic material sources 1600 passing through the mask patterns P of the mask-supply assembly 100 (100-1) may serve as a pixel 1700 of an OLED.

Since the mask pattern P is formed to have sloped sides (formed in a tapered shape), non-uniform deposition of the OLED pixels 700 due to shadow effect may be prevented by the organic material sources 1600 passing through the mask pattern P along the sloped direction.

As described above, a frame is formed by processing and connecting the support 30 to the mask 20 in a state in which a separate physical tension is not applied to the mask 20 after connecting the mask 20 onto the support 30 through electroforming. Thus, there is no risk of misalignment of the mask. Accordingly, the mask is clearly aligned so that stability of pixel deposition can be improved and at the same time an ultra-high resolution of 2,000 PPI or higher can be realized.

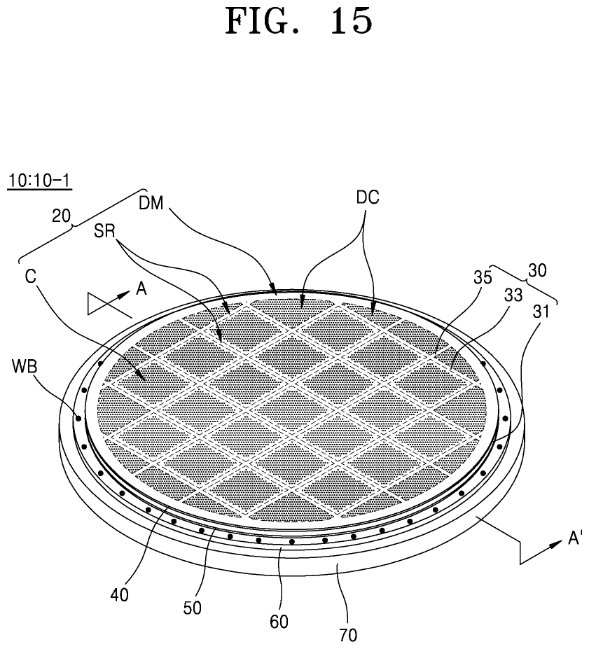

On the other hand, rather than using the mask-support assembly 100 (100-1) alone, a mask-frame assembly 10 may be configured by connecting the mask-support assembly 100 to an adhering support 200, as described below with reference to FIGS. 15 to 39.

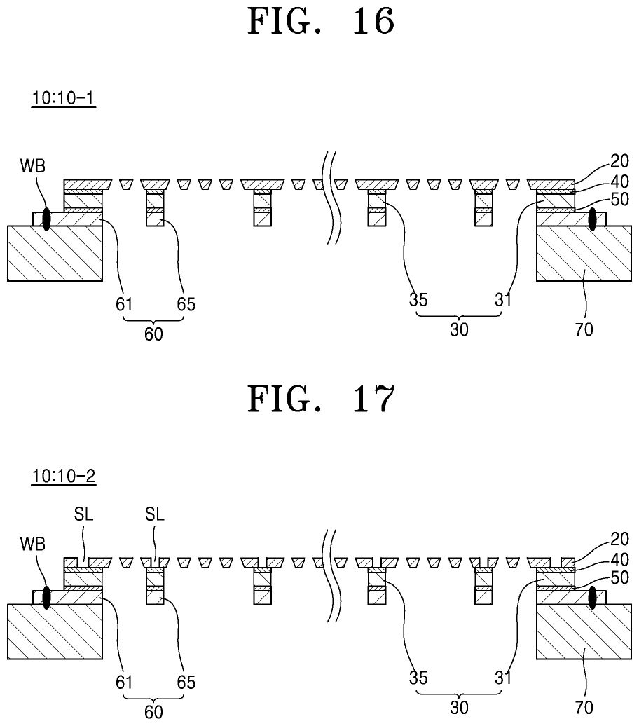

FIG. 15 is a schematic view showing a mask-frame assembly 10 (10-1) according to an embodiment of the present invention. FIG. 16 is a schematic cross-sectional view taken along line A-A′ of FIG. 15.

The mask-frame assembly 10 (10-1) may be provided by connecting a mask-support assembly 100 to the adhering support 200 (see FIG. 15). The mask-support assembly 100 (100-1 and 100-2) may include the mask 20 and the support 30. The adhering support 200 may include a contacting sheet portion 60 and a contacting frame 70. The contacting sheet portion 60 may be connected onto the contacting frame 70, the support 30 may be connected onto one surface of the contacting sheet portion 60, and the mask 20 may be connected onto one surface of the support 30. A support 30 and an adhering support 200 may serve as a frame that supports a mask 20. Thus, in this specification, a configuration in which the adhering support 200 is connected to the mask-support assembly 100 and the mask 20 is supported by the support 30 and the adhering support 200, wherein the support 30 and the adhering support 200 function as a frame, is proposed as the mask-frame assembly 10.

The configuration of the mask-support assembly 100 is the same as the description provided above in FIGS. 1 to 4, and thus detailed descriptions thereof will not be reiterated.

Referring to FIGS. 15 and 16, the adhering support 200 may include the contacting sheet portion 60 and the contacting frame 70.

The contacting sheet portion 60 may include an edge sheet portion 61, a plurality of first grid sheet portions 63, and a plurality of second grid sheet portions 65. Although the edge sheet portion 61, and the first and second grid sheet portions 63 and 65 are denoted by different names and reference numerals, the cell portion C, the edge sheet portion 61, and the first and second grid sheet portions 63 and 65 are not separated regions and are configured to be integrally formed with the same material. Hereinafter, the edge sheet portion 61 and the first and second grid sheet portions 63 and 65 may be used interchangeably with the contacting sheet portion 60.

The contacting sheet portion 60 preferably includes a magnetic material. In contrast, the support 30, which is a silicon wafer, may not include a magnetic material. For example, the contacting sheet portion 60 may include either Fe or Ni. Additionally, for example, the contacting sheet portion 60 may be made of an Invar or Super Invar material. With the inclusion of a magnetic material in the contacting sheet portion 60, in FIG. 39 to be described below, a magnetic field generated by a magnet 1310 pulls the contacting sheet portion 60 towards a target substrate 1900, and consequently, the mask 20 and the support 30 that are positioned above the contacting sheet portion 60 can attach to the target substrate 1900. As a result, twisting or sagging of the mask 20 and the support 30 due to load or tension may be prevented.

The contacting sheet portion 60 may have a shape corresponding to the support 30. The contacting sheet portion 60 may have the same shape as the support 30 shown in FIG. 3. Alternatively, as shown in FIGS. 15 and 16, the contacting sheet portion 60 may have a shape with a greater diameter than that of the support 30 such that its upper surface can entirely support the support 30, while the lower surface (edge sheet portion 61) can be connected to the contacting frame 70. However, the contacting sheet portion 60 does not necessarily have the same shape as the support 30, as long as the contacting sheet portion 60 can be connected to a lower part of the support 30 and transmit adhesion force to the mask 20 and support 30 that are positioned above it when a magnetic field is applied by the magnet 1310 (see FIG. 39). In this case, the cell portion C of the mask 20 and the cell region CR of the support 30 should remain uncovered and open by the contacting sheet portion 60.

The edge sheet portion 61 may have a circular shape corresponding to the edge portion 31 of the support 30.

The plurality of first grid sheet portions 63 may extend in the first direction and connect at both ends to the edge sheet portion 61. In addition, the plurality of second grid sheet portions 65 may extend in the second direction perpendicular to the first direction, intersecting with the first grid sheet portions 63, and connect at both ends to the edge sheet portion 61. The first grid sheet portions 63 are arranged in parallel to each other with predetermined intervals, and the second grid sheet portions 65 are also arranged in parallel to each other with predetermined intervals.

Since the first and second grid sheet portions 63 and 65 intersect with each other, empty spaces, in the form of a matrix, may appear at the intersecting portions, which may be in communication with the cell regions CR of the support 30. Empty spaces may also appear between the edge sheet portion 61 and the first and second grid sheet portions 63 and 65, and may be in communication with the dummy cell regions DCR of the support 30.

The contacting frame 70 may be connected to a lower part of the contacting sheet portion 60. The contacting frame 70 and the contacting sheet portion 60 may be connected to each other via a weld bead WB formed by welding. The lower surface of the edge sheet portion 61 may be connected to the upper surface of the contacting frame 70. The contacting sheet portion 60 and the contacting frame 70 may also be adhered to each other using adhesive instead of welding or utilizing a metal of the same material as an adhesive portion 50 to be described below.

The contacting frame 70 may also preferably includes a magnetic material, similar to the contacting sheet portion 60. For example, the contacting frame 70 may include either Fe or Ni. Meanwhile, if the purpose is to allow the adhering support 200 to transmit adhesion force to the mask 20 and support 30 that are positioned above it when a magnetic field is applied, at least one of the contacting sheet portion 60 or the contacting frame 70 may include a magnetic material.

The contacting frame 70 may be provided in a ring shape with a hollow region R. The contacting frame 70 may have a shape corresponding to the contacting sheet portion 60. The contacting frame 70 may have the same edge shape as the contacting sheet portion 60. Alternatively, as shown in FIGS. 15 and 16, the contacting frame 70 may have a shape with a greater diameter than that of the contacting sheet portion 60 to entirely support the edge sheet portion 61 of the contacting sheet portion 60 with its upper surface. However, the shape of the contacting frame 70 does not necessarily correspond to the shape of the contacting sheet portion 60, as long as the contacting frame 70 is connected to the contacting sheet portion 60 and can transmit adhesion force to the mask 20 and support 30 that are positioned above it when a magnetic field is applied by the magnet 1310 (see FIG. 39). In this case as well, the cell portion C of the mask 20 and the cell region CR of the support 30 should remain uncovered and open by the contacting frame 70.

The adhering support 200 needs to effectively transmit adhesion force upward when the magnetic field is applied by the magnet 1310, while also providing sufficient support to prevent deformation of the mask 20 and the support 30. Therefore, it is preferable for the adhering support 200 to have a thickness greater than the thickness of the support 30 so as to generate a strong magnetic force and possess strong rigidity. For example, the thickness of the support 30 may be approximately 50 μm to 200 μm, and the thickness of the adhering support 200 may be greater than the thickness of the support 30 and may be in the range of several millimeters (mm).

If the adhering support 200 is too thin, it may have weak rigidity and may not generate enough magnetic force. On the other hand, if the adhering support 200 is thicker than 10 mm, it may incur high manufacturing costs and pose difficulties in processing. In addition, in the adhering support 200, the thickness of the contacting sheet portion 60 may be thinner than the thickness of the contacting frame 70. In particular, the thickness of the first and second grid sheet portions 63 and 65 is preferably thin to prevent the shadow effect, as they need to be provided with the cell regions CR therebetween, through which an organic material 1600 passes. Taking this into account, for example, the thickness of the contacting sheet portion 60 of the adhering support 200 may be in the range of approximately 20 to 200 μm, corresponding to the mask 20 and the support 30, and preferably, may be approximately 100 μm or less. The contacting frame 70 may have a thickness of approximately 2 mm to 10 mm to provide sufficient rigidity, as it needs to support not only the contacting sheet portion 60 but also the mask-support assembly 10.

Meanwhile, an adhesive portion 200 may be interposed between the support 30 and the adhering support 200. The support 30 and the adhering support 200 may be connected to each other through the adhesive portion 50. The adhesive portion 50 may include at least one metal. For example, the adhesive portion 50 may be made of at least one of Cu, Ni, Au, Ag, Al, Sn, In, Bi, Zn, Sb, Ge, or Cd. Specific details of the adhesive portion 50 will be described further below.

FIG. 17 is a schematic cross-sectional view showing a mask-frame assembly 10 (10-2) according to another embodiment of the present invention.

As described above in FIG. 5, slit lines SL may be formed between each cell portion C of the mask-frame assembly 10 (10-2) of FIG. 17. Hereinafter, the description will be made assuming that the cell portions C of the mask 20 are spaced apart from each other by the slit lines SL.

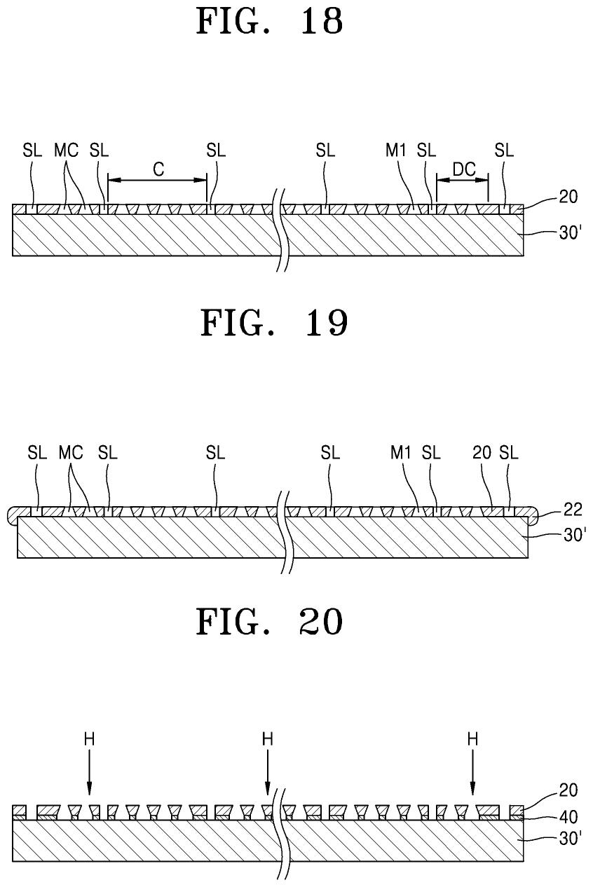

FIGS. 18 to 25 are schematic views showing a producing process of a mask-support assembly 100 (100-2) according to another embodiment of the present invention.

Referring to FIG. 18, a support 30′, which is a conductive substrate 30′, is prepared.

Then, a patterned insulating portion M1 may be formed on one surface of the conductive substrate 30′ (or support 30′). The insulating portion M1 is a part formed to protrude (embossed) from one surface of the connection portion 30′, and may have insulation properties to prevent the formation of a plated film (or mask 20). Accordingly, the insulating portion M1 may be made of at least one of photoresist, silicon oxides, or silicon nitrides. The insulating portion M1 may be formed by forming a silicon oxide or a silicon nitride on the support 30′ using deposition or the like, and thermal oxidation or thermal nitridation methods may be used employing the support 30′ as a base. A photoresist may be formed using a printing method or the like. The insulating portion M1 is preferably formed thicker than the plated film to be formed.

The insulating portion M1 preferably has a tapered shape. When a pattern in a tapered shape is formed using a photoresist, a multiple exposure method, a method of varying an exposure intensity per region, or the like may be used.

In addition to the insulating portion M1, a patterned insulating portion MC (or a dummy insulating portion MC) may be further formed on one surface of the support 30′. The insulating portion M1 may be formed on a region corresponding to the cell portion C and the insulating portion MC may be formed on a region corresponding to the dummy cell portion DC. The insulating portion MC may have the same shape as the insulating portion M1. The insulating portion MC and the insulating portion M1 may be formed together in the same process. The insulating portions M1 and MC may be formed at positions corresponding to the positions of the insulating portion M1 and the dummy insulating portion MC described above in FIG. 9.

Then, a mask 20 may be formed by performing electroforming on the support 30′. The electroforming process, the material of the mask metal film 20′, and the like, described above in FIG. 6 may be directly applied to the electroforming process for forming the mask 20, the material of the mask 20, and the like.

Since the insulating portion M1 has the insulating properties and thus a plated film is not formed on a region that corresponds to the insulating portion M1, the mask pattern P of the mask 20 may be constructed on the corresponding region. The mask pattern P (or insulating portion M1) may be formed on a region that corresponds to the cell portion C. Additionally, due to the insulating portion M1, slit lines SL between the cell portions C may also be formed during the electroforming process.

Also, since the insulating portion MC has the insulating properties, a plated film is not formed on a portion that corresponds to the insulating portion MC, allowing the construction of a dummy pattern DP of the mask 20. The dummy pattern DP (or insulating portion MC) may be formed on a region that corresponds to the dummy cell portion DC.

Referring to FIG. 19, electroforming may be performed such that the mask 20 is formed on the upper surface and the side surface of the support 30′, rather than being formed only on the upper surface of the support 30′. In the case of performing heat treatment H which will be described below, if the mask 20 is formed only on the upper surface of the support 30′, there is a risk that the edge portion of the mask 20 will be peeled off during the heat treatment H process. Thus, a plated film 22 may also be formed further on the side surface of the support 30′. Accordingly, as the plated film 22 on the side surface reinforces the adhesion to the support 30′ on the side surface of the support 30′, the entire mask 20 may not be peeled off during the heat treatment H process, and may be well fixed and attached to the support 30. The plated film on the side surface may be removed later by etching or laser cutting.

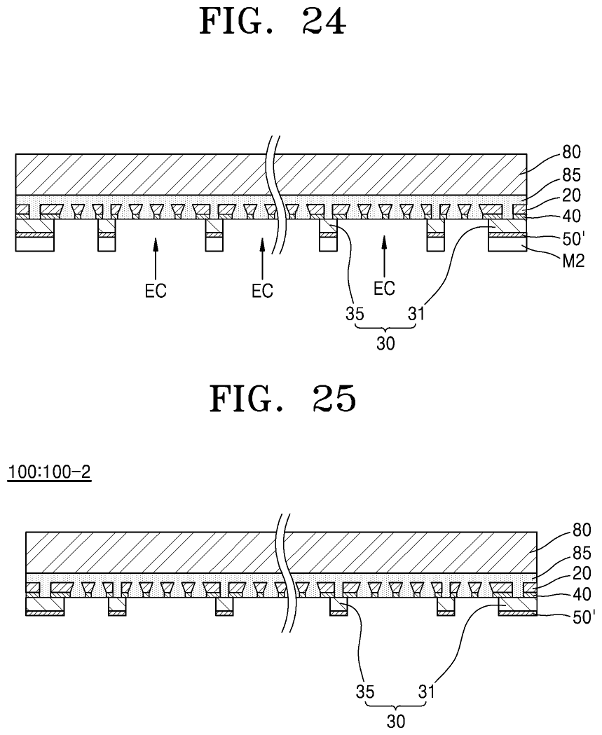

Then, referring to FIG. 20, heat treatment H may be performed on the mask 20 and the support 30′. The heat treatment may be performed at a temperature in the range of approximately 300° C. to 800° C. On the other hand, heat treatment may be performed after the thickness reduction process TN of the support 30′ shown in FIG. 22, or after the etching EC process of the support 30′ shown in FIG. 24, in addition to the step shown in FIG. 20.

Meanwhile, the cell portions C of the mask 20 may be spaced apart from each other by the slit lines SL. Consequently, independent residual stresses exist in each cell portion C during the heat treatment H of the mask 20. If the plurality of cell portions C are interconnected, residual stresses due to heat treatment H may occur across the entire portion of the mask 20, increasing the likelihood of deformation, where the edges of the cell portions C may peel away from the support 30 or bend during the heat treatment H process. Therefore, forming the slit lines SL between the cell portions C to separate them may reduce the residual stresses caused by heat treatment H.

Then, referring to FIG. 21, a template 80 may be adhered onto the mask 20 after removing the insulating portions M1 and MC. The template 80 serves as a medium to move the mask 20 in a state where it is adhered to and supported on one surface. The template 80 may have a flat plate shape with an area equal to or greater than that of the mask 20, ensuring support for the entire mask 20, and preferably has a circular shape corresponding to the form of the mask 20.

A material such as a wafer, glass, silica, quartz, alumina (Al₂O₃), borosilicate glass, or zirconia may be used for the template 80.

The template 30 may be adhered to the mask 20 with a temporary adhering portion 85 interposed therebetween. The temporary adhering portion 85 may be formed on one surface of the template 80 or the mask 20. The temporary adhering portion 85 may allow the mask 11/the support 30 to be temporarily adhered to one surface of the template 80 and supported on the template 30 until the thickness of the support 30′ is reduced (see FIG. 22) and an etching EC process is performed (see FIG. 24).

As the temporary adhering portion 85, a liquid wax, an adhesive, or an adhesive sheet that can be separated by any one of heat application, chemical treatment, UV application, or ultrasonic application may be used.

For example, a liquid wax may be used as the temporary adhering portion 85. The liquid wax may be the same as the wax used in a polishing process of a semiconductor wafer, and no particular limitation is imposed also on the type thereof. The liquid wax may include a material, such as acrylic, vinyl acetate, nylon, and various polymers as a resin component for controlling adhesion force, resistance to shock, etc., which mainly relate to retention force, along with a solvent. For example, the temporary adhering portion 85 may include acrylonitrile butadiene rubber (ABR) as a resin component, and SKYLIQUID ABR-4016 containing n-propyl alcohol as a solvent component. The liquid wax may be formed using spin coating.

The temporary adhering portion 85, which is a liquid wax, may have low viscosity at a temperature higher than 85° C. to 100° C., and may have increased viscosity and be partially solidified at a temperature lower than 85° C., allowing the mask 20 and the template 80 to be fixed and adhered to each other.

The temporary adhering portion 85 may be filled in at least a portion between the mask 20 and the mask patterns P. Accordingly, the mask 20/the support 30′ are allowed to be more strongly adhered to and supported by the template 80, and deformation may be effectively prevented in a thickness reduction process TN of the support 30′, which will be described below. Then, referring to FIG. 22, after the mask 20/the support 30′ is adhered onto the template 80, the thickness reduction process TN of the support 30′ (or conductive substrate 30′) may be performed. The thickness reduction process TN may be performed on a lower surface (second surface), which is opposite to the upper surface (first surface) of the support 30′ in contact with the mask 20. The thickness reduction process TN may be performed using lapping, polishing, buffing, etc.

To ensure that the adhering support 200 can sufficiently transmit adhesion force to the mask 20 and support 30 that are positioned above it when a magnetic field is applied by the magnet 1310 (see FIG. 39), the thickness of the mask 20/the support 30 should be thin. Since the thickness of the mask 20 is approximately 2 μm to 12 μm, which is sufficiently thin, the thickness of the support 30′ needs to be further reduced. For example, the support 30′ (or conductive substrate 30′), which is a silicon wafer, has a thickness of approximately 725 μm, and hence its thickness needs to be reduced. In addition, the thickness of the support 30′ needs to be appropriately reduced such that it has sufficient rigidity to support the mask 20 and can be tensioned on a cell portion-by-cell portion basis (see FIGS. 28 to 30). Taking this into account, the thickness of the support 30′ after the thickness reduction process TN may be approximately 50 μm to 200 μm.

If the thickness reduction process TN of the support 30′ is directly performed, the support 30 becomes thin and its rigidity is lowered, which may cause twisting or warpage. However, according to the present invention, the template 80 adheres to and supports the mask 20/the support 30′, thus preventing deformation of the support 30′ during the thickness reduction process TN.

On the other hand, the mask 20/the support 30′ may be fixed to a holder (not shown), a gripper (not shown), or the like, without being adhered to and supported by the template 80 with a plate shape, such as wafer, glass, or the like, before undergoing the thickness reduction process TN.

Next, referring to FIG. 23, an adhesive portion 50′ may be formed on a lower surface (second surface) of the support 30′ (or conductive substrate 30′) reduced in thickness. The lower surface (second surface) is opposite to an upper surface (first surface) that comes in contact with the mask 20. The adhesive portion 50′ may include at least one of Cu, Ni, Au, Ag, Al, Sn, In, Bi, Zn, Sb, Ge, or Cd. The adhesive portion 50′ may be formed by sputtering, brazing, or other methods that enable easy deposition of a thin film without material limitations, but is not limited thereto.

In order to impart etch resistance, an insulating portion M2 may be formed on the lower surface of the support 50′ excluding the portions corresponding to the cell portions C and the dummy cell portions DC. The insulating portion M2 may be formed of photoresist using a printing method or the like, and may be formed of silicon oxide or silicon nitride serving as a hard mask by a method such as thermal oxidation or thermal nitridation. Meanwhile, a metal may be used as a mask for etching.

Then, referring to FIG. 24, the support 30′ (or conductive substrate 30′) may be subjected to etching EC. The etching EC process of the support 30′ is the same as described above in FIG. 13.

According to another embodiment, the insulating portion M2 may be directly formed on the lower surface (second surface) of the support 30′ without forming the adhesive portion 50′ in the step shown in FIG. 23. Then, the support 30′ (or conductive substrate 30′) may be subjected to etching EC. Thereafter, the adhesive portion 50′ may be formed on the lower surfaces of the edge portion 31 and first and second grid portions 33 and 35.

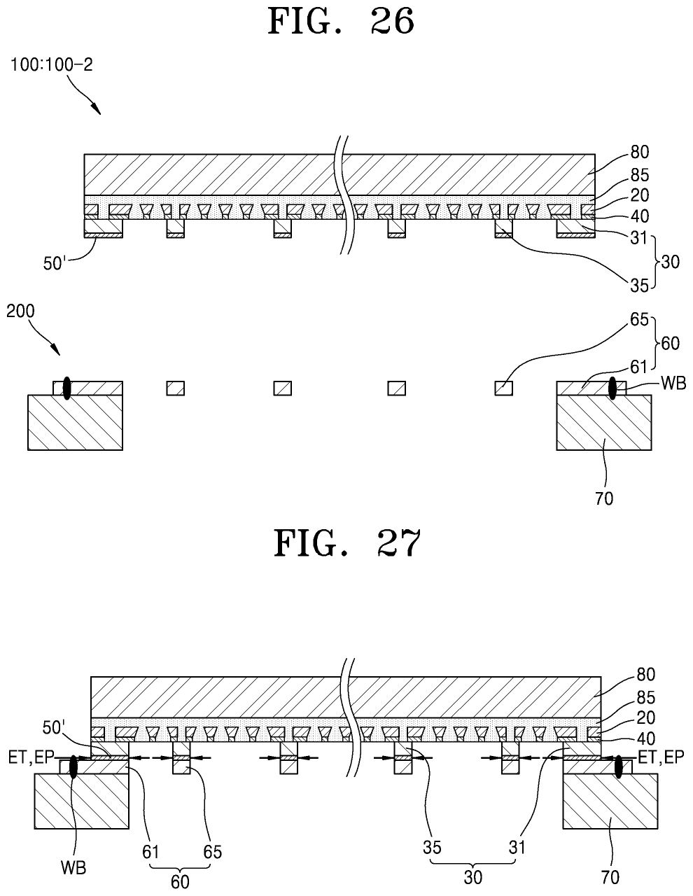

According to another embodiment, the adhesive portion 50′ may not be formed on the lower surface of the support 30; instead, it may be formed on the upper surface of the adhering support 200 (or contacting sheet portion 60), as will be described below in FIG. 26.

Thereafter, referring to FIG. 25, the insulating portion M2 may be removed. Then, after completing subsequent treatment processes, such as cleaning, the mask-support assembly 100 (100-2) may be obtained. The connection portion 40 may be formed between the mask 20 and the support 30, and the adhesive portion 50′ may be formed on a lower part of the support 30.

FIGS. 26 and 27 are schematic views showing a producing process of a mask-frame assembly 10 according to an embodiment of the present invention. A support 30 and an adhering support 200 may serve as a frame that supports a mask 20.

Referring to FIG. 26, an adhering support 200 may be provided. The adhering support 200 may be provided in a state where a contacting sheet portion 60, include an edge sheet portion 61, a plurality of first grid sheet portions 63, and a plurality of second grid sheet portions 65, is connected to a contacting frame 70. For example, the contacting sheet portion 60 and the contacting frame 70 may be connected to each other via a weld bead WB formed by welding. Alternatively, a form of adhering support 200 may be provided, which integrally includes the contacting sheet portion 60 and the contacting frame 70 by performing etching, processing, or the like on a disc-shaped material.

Next, referring to FIG. 27, an upper part of the adhering support 200 may be brought into corresponding contact with a lower part of the support 30. The adhering support 200 may contact the support 30 via the adhesive portion 50′.

Optionally, a process of separating a template 80 from the mask 20 (or mask-support assembly 100) may be further performed. The template 80 may be separated from the mask 20 (or mask-support assembly 100) by applying at least one of heat, chemical treatment, ultrasound waves, or UV light to a temporary adhering portion 85. For example, when heat with a temperature higher than 85° C. to 100° C. is applied, the viscosity of the temporary adhering portion 85 is lowered and the adhesion between the template 80 and the mask 20 is reduced so that the template 80 can be separated from the mask 20. In another example, the template 80 may be separated by dissolving or removing the temporary adhering portion 85 through immersion in a chemical substance, such as IPA, acetone, ethanol, or the like. In another example, applying ultrasound waves or UV light may cause the adhesion between the template 80 and the mask 20 to weaken, leading to the separation of the template 80.

Optionally, the template 80 may not be separated. In this case, there is an advantage in that the template 80 can uniformly apply pressure from above during the subsequent process of connecting the mask-support assembly 100 and the adhering support 200 through the adhesive portion 50′. FIG. 27 illustrates the state where the template 80 is not separated, while FIGS. 28 to 30 illustrate the state where the template 80 is separated.

Subsequently, at least one of heat ET or pressure EP may be applied to the support 30, the adhesive portion 50′, and the adhering support 200. Heat treatment may be carried out by applying heat ET to the support 30, the adhesive portion 50′, and the adhering support 200. Alternatively, heat ET and pressure EP may be simultaneously applied to the support 30, the adhesive portion 50′, and the adhering support 200 to conduct heat treatment with less heat ET.

Heat treatment by the application of heat ET and/or pressure EP may be carried out within the range where the adhesive portion 50′ can connect the support 30 and the adhering support 200. For example, metals in the adhesive portion 50′ may be melted by heat treatment and then solidified again, connecting the support 30 and the adhering support 200. In another example, the connection may be achieved by altering the interfacial state between the support 30 and the adhering support 200 in a manner that metal components of the adhesive portion 50′ diffuse into the support 30 and the adhering support 200, or conversely, the components of the support 30 and the adhering support 200 diffuse into the adhesive portion 50′, or in a manner that the components of the support 30, the adhering support 200, and the adhesive portion 50′ diffuse mutually into each other.

Heat treatment may be performed at temperatures ranging from 200° C. to 800° C., preferably in the low-temperature range of approximately 200° C. to 400° C.

Following the heat treatment, subsequent processes such as cleaning may be performed to complete the producing of the mask-frame assembly 10 as shown in FIGS. 16 and 17. The form in which the support 30 and the adhering support 200 are connected through an adhesive portion 50, the support 30 includes the edge portion 31 and the first and second grid portions 33 and 35, and the mask 20 is connected onto the support 30 may be provided. The cell portion C of the mask 20 may be provided as an area with an open lower part without support from the support 30/the adhering support 200, providing the movement path of the organic material sources 1600 during the OLED pixel deposition process.

FIGS. 28 to 30 are schematic views specifically showing a process of connecting the support 30 and the adhering support 200 during the producing process of a mask-frame assembly 10 according to an embodiment of the present invention, showing a schematic cross-sectional view (a) and a schematic plan view (b).

As described above in FIG. 27, heat ET and pressure EP may be applied to the surrounding areas of all cell portions C to connect the support 30 and the adhering support 200 (or contacting sheet portion 60) through the adhesive portion 50′. Alternatively, as shown in FIGS. 28 to 30, the support 30 and the adhering support 200 (or contacting sheet portion 60) may be sequentially connected on the surrounding area of each cell portion C.

First, referring to FIG. 28, heat ET and pressure EP may be applied only to the surrounding area of the cell portion C1 located at the center of the mask 20 among the cell portions C. The adhesive portion 50′ on the surrounding area of the cell portion C1 may mediate the connection between the support 30 (grid portions 33 and 35) and the adhering support 200 (grid sheet portions 63 and 65). The portion of the adhesive portion 50′ connecting the support 30 and the adhering support 200 in the surrounding area of the cell portion C1 is represented by a shaded rectangle in (b) of FIG. 28.

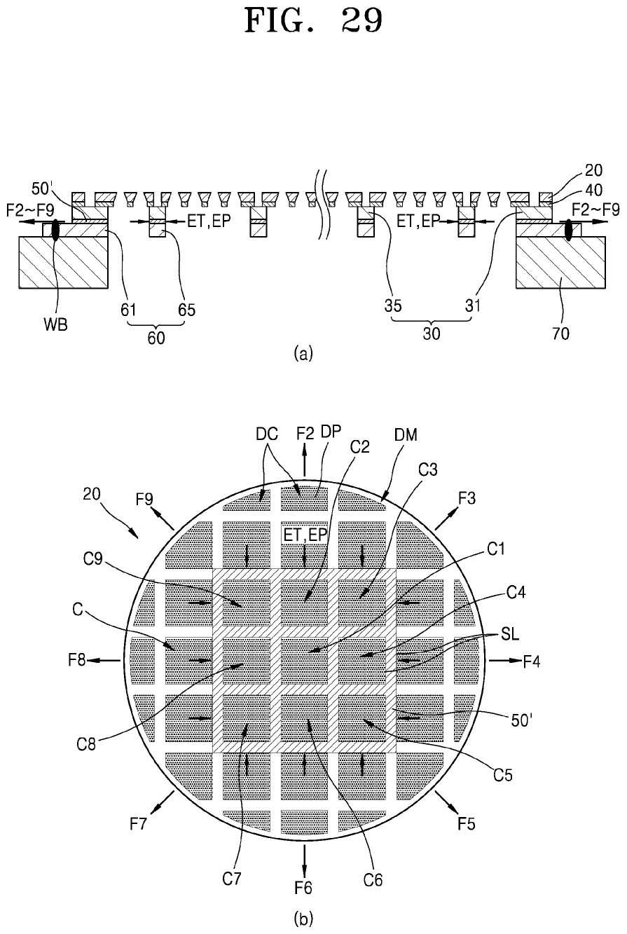

Next, referring to FIG. 29, heat ET and pressure EP may be applied only to the surrounding areas of eight cell portions C2 to C9 neighboring the cell portion C1. The adhesive portion 50′ on the surrounding areas of the cell portions C2 to C9 may mediate the connection between the support 30 (grid portions 33 and 35) and the adhering support 200 (grid sheet portions 63 and 65).

Since the surrounding area of cell portion C1 already has the adhesive portion 50 formed, fixing the connection between the support 30 and the adhering support 200, tensile forces F2 to F9 may be applied in a radial direction to the edges of the mask 20 and the support 30. Since the template 80 is in a separated state, the position alignment of each cell portion C2 to C9 may be further controlled by adjusting the tensile forces F2 to F9. Heat ET and pressure EP may be applied simultaneously to the surrounding areas of all eight cell portions C2 to C9. Due to the relatively thin thickness of the support 30, ranging from approximately 50 μm to 200 μm, the application of tensile forces F2 to F9 allows for position alignment of the cell portions C2 to C9.

Alternatively, tensile forces F2 to F9 may be applied sequentially from the cell portion C2 to the cell portion C9 in a radial direction or in a 360-degree direction and heat ET and pressure EP may be sequentially applied to the surrounding areas of the cell portions C2 to C9, allowing the adhesive portion 50 to connect the support 30 and the adhering support 200. For example, in a state where tensile force F2 is applied in the upward direction to the mask 20 and the support 30, heat ET and pressure EP may be applied to the surrounding area of the cell portion C2, so that the support 30 and the adhering support 200 can be connected to the periphery of the cell portion C2 through the adhesive portion 50. Subsequently, in a state where tensile force F3 is applied in the upper right direction to the mask 20 and the support 30, heat ET and pressure EP may be applied to the surrounding area of the cell portion C3, so that the support 30 and the adhering support 200 can be connected to the periphery of the cell portion C3 through the adhesive portion 50. Subsequently, in a state where tensile force F4 is applied in the right direction to the mask 20 and the support 30, heat ET and pressure EP may be applied to the surrounding area of the cell portion C4, so that the support 30 and the adhering support 200 can be connected to the periphery of the cell portion C4 through the adhesive portion 50. In a state where the surrounding areas of the cell portions C2 to C9 are sequentially aligned by repeating the above process, the support 30 and the adhering support 200 may be connected.

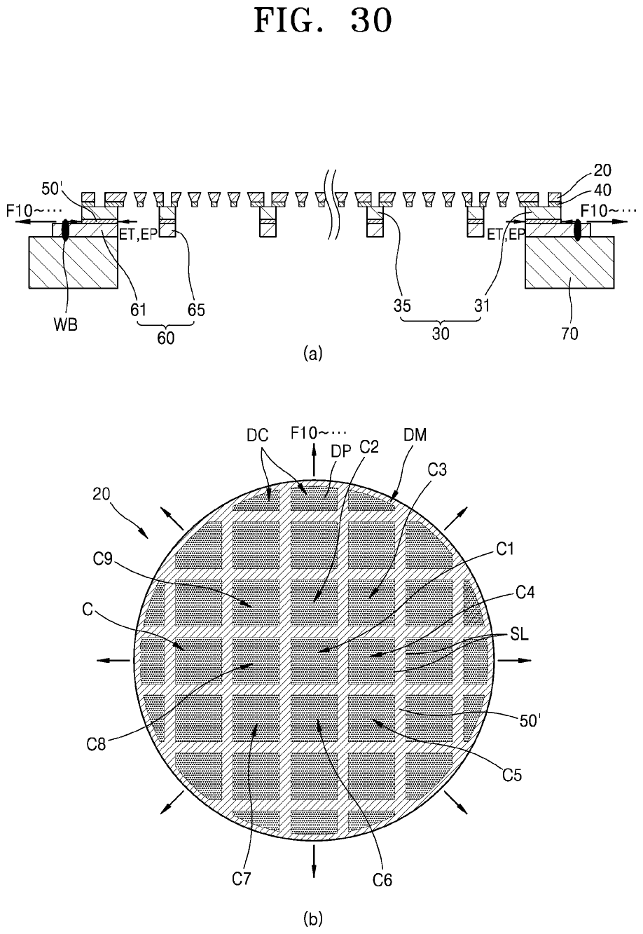

Next, referring to FIG. 30, heat ET and pressure EP may also be applied to the surrounding areas of cell portions C neighboring the eight cell portions C2 to C9 shown in FIG. 29. The support 30 and the adhering support 200 in the surrounding areas of the cell portions C neighboring the eight cell portions C2 to C9 may be connected simultaneously or sequentially in a radial direction. In the dummy portion DM of the mask 20, the support 30 and the adhering support 200 may also be connected through the adhesive portion 50. During the process of adhering the cell portions C neighboring the eight cell portions C2 to C9, tensile forces F10, and so on may be applied to the edges of the mask 20 and the support 30 in a radial direction. This process may be repeated to connect the support 30 and the adhering support 200 on the surrounding areas of all cell portions C.

As described above, the present invention achieves the initial connection of the support 30 and the adhering support 200 around the central cell portion C1, and sequentially aligns the positions of the outer cell portions C and establishes connections of the support 30 and the adhering support 200 around the corresponding cell portions C. This process ensures a clear distinction of the positions of each cell portion C and the mask pattern P of the corresponding cell portion C. Accordingly, the variation in pixel position accuracy (PPA) between each cell portion C may be minimized.

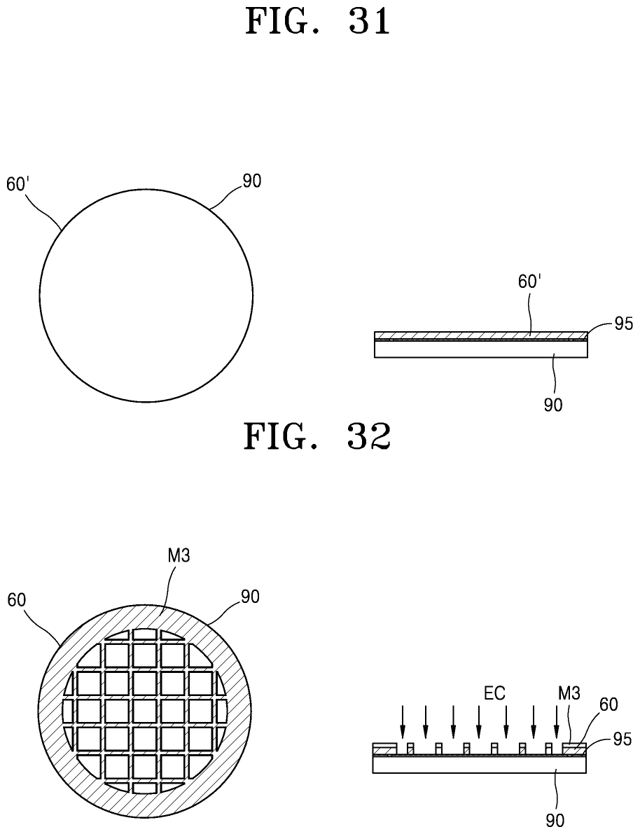

FIGS. 31 to 36 are schematic views showing a process of producing an adhering support 200 according to an embodiment of the present invention.

Referring to FIG. 31, a second template 90 may be prepared. The second template 90 serves as a medium to move the contacting sheet portion 60′ in a state where it is adhered to and supported on one surface. The second template 80 may have a flat plate shape with an area equal to or greater than that of the contacting sheet portion 60′, ensuring support for the entire contacting sheet portion 60′. The contacting sheet portion 60′ may be a metal film (or a contacting metal film) without an edge sheet portion 61 and grid sheet portions 63 and 65.

The second template 90 may be made of the same material as the template 80 described above in FIG. 21. In addition, the second template 90 may be attached to the contacting sheet portion 60′ with a second temporary adhering portion 95 interposed therebetween. The second temporary adhering portion 95 may be made of the same material as the temporary adhering portion 85 described above in FIG. 21. A method of adhering the second template 90 and the contacting sheet portion 60′ by interposing the second temporary adhering portion 95 may be the same as the method described above in FIG. 21.

The contacting sheet portion 60′ (or contacting metal film) may be provided with a thickness of approximately 20 to 200 μm, preferably, a thickness of 100 μm or less. For example, a contacting sheet portion 60′ that is reduced to 100 μm or less by performing a thickness reduction process on a metal sheet made of an Invar material may be used.

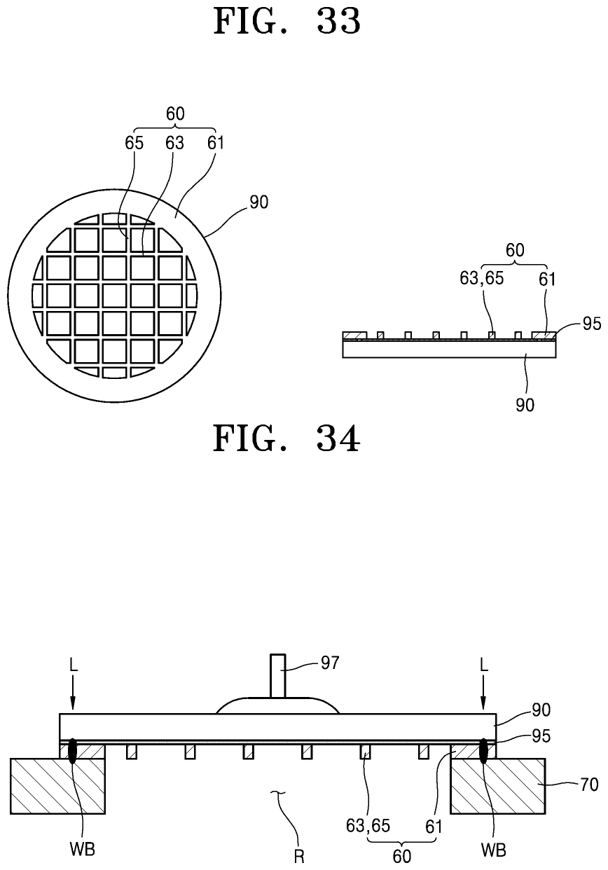

Next, referring to FIG. 32, a patterned insulating portion M3 may be formed on the contacting sheet portion 60′. The insulating portion M3 may be formed of a photoresist material through a method such as printing or the like.

Then, etching EC of the contacting sheet portion 60′ may be performed. Various methods such as dry etching, wet etching, and the like may be employed without limitations, and a portion of the contacting sheet portion 60′ exposed to an empty space between the insulating portions M3 may be etched EC. The etched portion of the contacting sheet portion 60′ is of a size corresponding to a microdisplay of approximately 1 to 2 inches and may be provided to be in communication with the cell regions CR/dummy cell regions DCR of the support 30. After etching EC process, the contacting sheet portion 60′ (or contacting metal film) may become a contacting sheet portion 60 with an edge sheet portion 61 and first and second grid sheet portions 63 and 65 formed thereon.

Next, referring to FIG. 33, the second template 90 that supports the contacting sheet portion 60 may be produced by removing the insulating portion M3.

Then, referring to FIG. 34, the second template 90 on which the contacting sheet portion 60 is adhesively supported may be loaded onto the contacting frame 70. The second template 90 may be moved by a chuck 97. For example, the second template 90 may be transferred by being held by a vacuum chuck 97 on a side opposite to the surface on which the contacting sheet portion 60 is adhered.

The contacting sheet portion 60 may be in corresponding contact with the contacting frame 70. That is, the edge sheet portion 61 of the contacting sheet portion 60 may be in corresponding contact with the upper surface of the contacting frame 70. Loading the second template 90 onto the contacting frame 70 may align the contacting sheet portion 60 with the contacting frame 70. As the second template 90 presses the contacting sheet portion 60, the contacting sheet portion 60 and the contacting frame 70 may be brought into close contact.

Thereafter, by irradiating a laser L between the contacting sheet portion 60 and the contacting frame 70, the contacting sheet portion 60 may be attached to the contacting frame 70 through laser welding. Weld beads WB may be formed between the laser-welded edge sheet portion 61 and the contacting frame 70, and the contacting sheet portion 60 may be connected to the contacting frame 70 through the weld beads WB. The weld beads WB may be formed at regular intervals along the formation direction of the edge sheet portion 61.

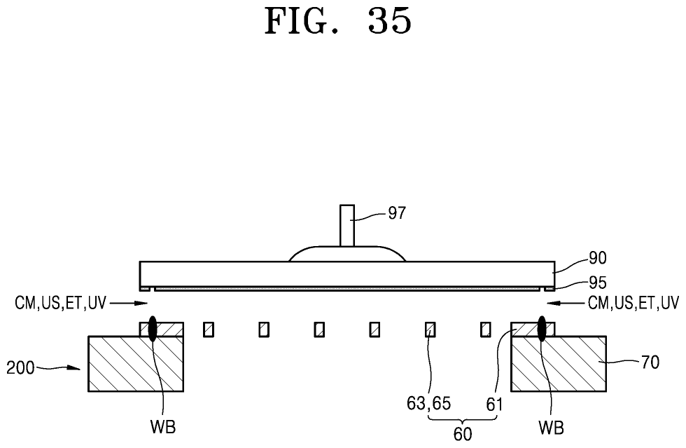

Next, referring to FIG. 35, after connecting the contacting sheet portion 60 and the contacting frame 70, the second template 90 may be debonded from the contacting sheet portion 60. The process of separating the template 80 from the mask 20, as described in FIG. 27, may be applied without modifications. The debonding of the contacting sheet portion 60 and the second template 90 may be performed through the application of at least one of heat ET, chemical treatment CM, ultrasound US, or UV irradiation UV to a second temporary adhering portion 95.

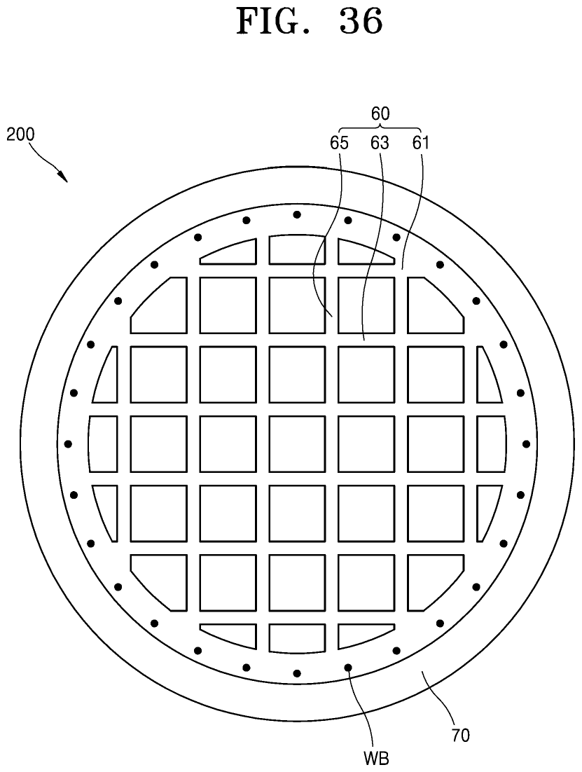

As a result, as shown in FIGS. 35 and 36, the form in which the contacting sheet portion 60 is connected to the contacting frame 70 is produced. This may be provided as an adhering support 200.

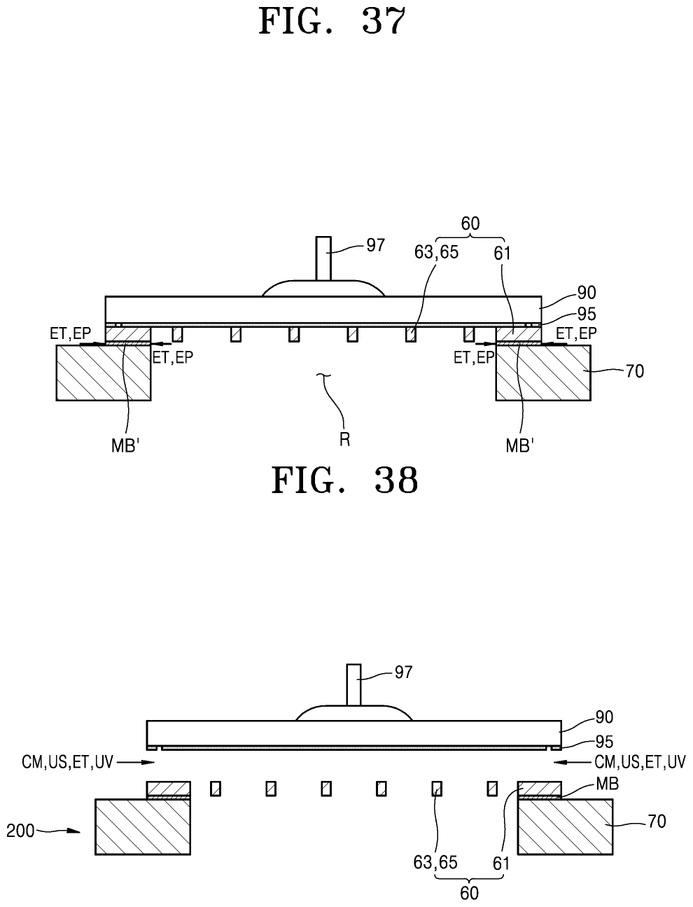

FIGS. 37 and 38 are schematic views showing a process of producing an adhering support 200 according to another embodiment of the present invention. The process of preparing a second template 90 with a contacting sheet portion 60 adhered thereto is the same as the process shown in FIGS. 31 to 33.

Then, referring to FIG. 37, the second template 90 on which the contacting sheet portion 60 is adhesively supported may be loaded onto the contacting frame 70. In this case, a metal adhesive portion MB′ may be interposed between the contacting sheet portion 60 and the contacting frame 70. The metal adhesive portion MB′ may be formed on a lower surface of the contacting sheet portion 60 that faces the contacting frame 70. Alternatively, the metal adhesive portion MB′ may be formed on an upper surface of the contacting frame 70 that faces the contacting sheet portion 60. The metal adhesive portion MB′ may be formed of the same material and in the same manner as the adhesive portion 50′ described above in FIG. 23.

Subsequently, at least one of heat ET or pressure EP may be applied to the metal adhesive portion MB′. Heat treatment may be carried out by applying heat ET to the contacting sheet portion 60, the metal adhesive portion MB′, and the contacting frame 70. Alternatively, heat ET and pressure EP may be simultaneously applied to the contacting sheet portion 60, the metal adhesive portion MB′, and the contacting frame 70 to conduct heat treatment with less heat ET.

Heat treatment by the application of heat ET and/or pressure EP may be carried out within the range where the metal adhesive portion MB′ can connect the contacting sheet portion 60 and the contacting frame 70. For example, metals in the metal adhesive portion MB′ may be melted by heat treatment and then solidified again, connecting the contacting sheet portion 60 and the contacting frame 70. In another example, the connection may be achieved by altering the interfacial state between the contacting sheet portion 60 and the contacting frame 70 in a manner that metal components of the metal adhesive portion MB′ diffuse into the contacting sheet portion 60 and the contacting frame 70, or conversely, the components of the contacting sheet portion 60 and the contacting frame 70 diffuse into the metal adhesive portion MB′, or in a manner that the components of the contacting sheet portion 60, the metal adhesive portion MB′, and the contacting frame 70 diffuse mutually into each other.

Heat treatment may be performed at temperatures ranging from 200° C. to 800° C., preferably in the low-temperature range of approximately 200° C. to 400° C.

Next, referring to FIG. 38, after connecting the contacting sheet portion 60 and the contacting frame 70, the second template 90 may be debonded from the contacting sheet portion 60. The process of debonding the template 80 from the mask 20, as described in FIG. 24, may be applied without modifications.

FIG. 39 is a schematic diagram illustrating an organic light emitting diode (OLED) pixel deposition apparatus 1000 to which a mask-frame assembly 10 according to one embodiment of the present invention is applied.

Referring to FIG. 39, the mask-frame assembly 10 for enabling deposition of the organic material source 1600 per pixel may be positioned in contact with or very close to the target substrate 1900. The magnet 1310 may generate a magnetic field and the mask-frame assembly 10 may adhere to the target substrate 1900 due to the attraction by the magnetic field. In this case, since the adhering support 200 (60 and 70) containing a magnetic material is pulled toward the target substrate 1900 from the bottom, the mask 20 and the support 30 are brought into contact with the target substrate 1900 as the adhering support 200 pushes them upward. Furthermore, during the process in which the adhering support 200 pushes up the mask 20 and the support 30 onto the target substrate 900, issues of unevenness, such as sagging due to self-weight or distortion caused by tension, may also be addressed.

The deposition source supply 1500 may supply the organic material sources 1600 while horizontally reciprocating, and the organic material sources 1600 supplied from the deposition source supply 1500 may pass through mask patterns P formed on the mask-frame assembly 10 and be deposited on a surface of the target substrate 1900. The deposited organic material sources 1600 passing through the mask patterns P of the mask-frame assembly 10 may serve as a pixel 1700 of an OLED.

As described above, the present invention involves forming a frame by processing and connecting the support 30 and the adhering support 200 without applying a separate physical tension to the mask 20 after forming the mask 20 on the support 30 through electroforming, and thus there is no risk of misalignment of the mask. Accordingly, the mask is clearly aligned so that stability of pixel deposition can be improved and at the same time an ultra-high resolution of 2,000 PPI or higher can be realized.

According to the present invention configured as described above, it is possible to achieve ultra-high-resolution pixels for a microdisplay.

In addition, according to the present invention, it is possible to improve the stability of pixel deposition by allowing a mask to be clearly aligned.

In addition, according to the present invention, it is possible to achieve a uniform stress level in all parts of a mask.

In addition, according to the present invention, a mask and a frame can be brought into close contact with a target substrate without sagging due to load during an OLED pixel formation process.

However, the scope of the present invention is not limited by the above effects.

While the present invention has been particularly shown and described with reference to embodiments thereof, it will be understood by one of ordinary skill in the art that various changes in form and details may be made therein without departing from the scope of the present invention as defined by the following claims.

### REFERENCE NUMERALS

10: MASK-FRAME ASSEMBLY
20: MASK
30: SUPPORT
31: EDGE PORTION
33, 35: FIRST AND SECOND GRID PORTION
40: CONNECTION PORTION
50: ADHESIVE PORTION
60: CONTACTING SHEET PORTION
61: EDGE SHEET PORTION
63, 65: FIRST AND SECOND GRID SHEET PORTION
70: CONTACTING FRAME
80: TEMPLATE
90: SECOND TEMPLATE
100: MASK-SUPPORT ASSEMBLY
200: ADHERING SUPPORT
1000: OLED PIXEL DEPOSITION APPARATUS
C, SR, DM: CELL PORTION, SEPARATION PORTION, DUMMY PORTION
DC: DUMMY CELL PORTION
DP: DUMMY PATTERN
P: MASK PATTERN
SL: SLIT LINE
WB: WELD BEAD

1. A producing method of a mask-support assembly for use in a process of forming OLED pixels on a semiconductor wafer, the producing method comprising the steps of:
(a) preparing a support;
(b) forming a mask metal film on a first surface of the support; and
(c) forming a mask including a mask pattern by etching the mask metal film.

2. The producing method of claim 1, wherein the support is a silicon wafer.

3. The procuring method of claim 2, wherein in step (b), the mask metal film made of an Invar or Super Invar material is formed on the substrate by an electroforming method.

4. The producing method of claim 1, further comprising, between steps (a) and (b),
(a2) forming a connection portion including at least one of Ni, Cu, Ti, Au, Ag, Al, Sn, In, Bi, Zn, Sb, Ge, or Cd.

5. The producing method of claim 4, wherein in step (b), the mask metal film is formed on the connection portion by an electroforming method or the mask metal film produced by a rolling method is disposed on the connection portion.

6. The producing method of claim 1, further comprising, between steps (b) and (c), performing heat treatment on the mask metal film and the support.

7. The producing method of claim 6, wherein a connection portion including at least one of Fe, Ni, or Si is formed between the mask metal film and the support.

8. The producing method of claim 4, further comprising, between steps (b) and (c), performing heat treatment on the mask metal film and the support,
wherein the mask metal film and the support are connected through the connection portion after the heat treatment.

9. The producing method of claim 6, wherein the heat treatment is performed at a temperature in a range of 100° C. to 800° C.

10. The producing method of claim 1, wherein in step (c), an insulating portion including at least one of photoresist, silicon oxide, or silicon nitride is formed on an upper part of the mask metal film, and the mask metal film exposed between the insulating portions is etched.

11. The producing method of claim 10, wherein the mask metal film is etched using at least one of dry etching, wet etching, or laser etching.

12. The producing method of claim 1, further comprising forming a support including an edge portion and a grid portion by etching the support on a second surface opposite to the first surface of the support.

13. The producing method of claim 12, wherein the support and the mask have a circular shape, and
the grid portion includes a plurality of first grid portions extending in a first direction and having both ends connected to the edge portion; and a plurality of second grid portions extending in a second direction perpendicular to the first direction, intersecting with the first grid portions, and having both ends connected to the edge portion.

14. The producing method of claim 13, further comprising, between steps (c) and (d):
(c2) adhering a template onto the mask through a temporary adhering portion; and
(c3) reducing a thickness of at least a portion where the grid portion is to be formed to 50 μm to 200 μm on the second surface of the support.
